(19) United States
(12) Patent Application Publication
(10) Pub. No.: US 2023/0083612 A1
(43) Pub. Date: Mar. 16, 2023

(54) DISPLAY DEVICE

(71) Applicant: Samsung Display Co., Ltd., Yongin-si (KR)

(72) Inventors: Bo Kwang Song, Hwaseong-si (KR); Gee Bum Kim, Seoul (KR); Kwang Soo Bae, Yongin-si (KR); Dae Young Lee, Seoul (KR); Min Oh Choi, Yongin-si (KR)

(21) Appl. No.: 17/661,820

(22) Filed: May 3, 2022

(30) Foreign Application Priority Data
Sep. 9, 2021 (KR) 10-2021-0120390

(51) Int. Cl. H01L 51/52; H01L 27/32

(52) U.S. Cl. CPC H01L 51/5284; H01L 27/3246; H01L 27/3227

(57) ABSTRACT

A display device includes a substrate, a plurality of light-emitting units disposed on the substrate and that emit light, a bank layer disposed on the substrate and that partitions the plurality of light-emitting units, a plurality of light-sensing units disposed on the substrate and that sense incident light, and a light-shielding layer disposed on the bank layer and that includes a light-shielding opening that overlaps each of the light-sensing units. At least a part of the light-shielding opening overlaps the bank layer.

### CROSS REFERENCE TO RELATED APPLICATIONS

This application claims priority under 35 U.S.C. § 119 from US Provisional Application No. 10-2021-0120390, filed on Sep. 9, 2021 in the Korean Intellectual Property Office, the contents of which are herein incorporated by reference in their entirety.

### 1. TECHNICAL FIELD

Embodiments of the disclosure are directed to a display device.

### 2. DISCUSSION OF THE RELATED ART

As the information-oriented society evolves, various demands for display devices are ever increasing. For example, display devices are used by a variety of electronic devices, such as smart phones, digital cameras, laptop computers, navigation devices, smart watches, and smart televisions. Display devices include flat panel display devices, such as liquid-crystal display devices, field emission display devices, and organic light-emitting display devices.

Research and development is being conducted for integrating sensors that can recognize touches or fingerprints into such display devices. To increase the accuracy of recognizing fingerprints, a region or area of light incident on each light-sensing unit should be narrowed. If the area is narrowed, however, the sizes of the openings of a light-shielding layer and photo sensors are reduced, and thus the amount of light received by the photo sensors may be reduced.

### SUMMARY

Embodiments of the disclosure provide a display device that includes a finger sensor that can pass a sufficient amount of light for a photo sensor while maintaining the accuracy of fingerprint sensing.

According to an embodiment of the disclosure, a display device includes a substrate, a plurality of light-emitting units disposed on the substrate and that emit light, a bank layer disposed on the substrate and that partitions the plurality of light-emitting units, a plurality of light-sensing units disposed on the substrate and that sense incident light, and a light-shielding layer disposed on the bank layer and that includes a light-shielding opening that overlaps each of the light-sensing units. At least a part of the light-shielding opening overlaps the bank layer.

The plurality of light-emitting units may include a first light-emitting unit disposed on one side of one of the plurality of light-sensing units; and a second light-emitting unit disposed on an opposite side of the one of the plurality of light-sensing units, and the light-shielding opening is located adjacent to the first light-emitting unit.

The light-shielding layer may further include a first light-emitting opening that overlaps the first light-emitting unit; and a second light-emitting opening that overlaps the second light-emitting unit.

A minimum distance between the first light-emitting opening and the light-shielding opening is defined as a first distance, and a minimum distance between the second light-emitting opening and the light-shielding opening is defined as a second distance. The first distance differs from the second distance.

A difference between the first distance and the second distance may be greater than a distance between a center of one of the light-sensing units and a center of a light-shielding opening that overlaps the one of the light-sensing units.

A distance between a center of one of the light-sensing units and a center of a light-shielding opening that overlaps the one of the light-sensing units may be at least half a length of one of the light-sensing units.

The display device may further include an emissive layer disposed in each of the light-emitting units, a photoelectric conversion layer disposed in each of the light-sensing units, and a common electrode disposed on the emissive layer and the photoelectric conversion layer.

According to another embodiment of the disclosure, a display device includes a substrate, a plurality of light-emitting units disposed on the substrate and that emit light, a bank layer disposed on the substrate and that partitions the plurality of light-emitting units, a plurality of light-sensing units disposed on the substrate and that sense incident light, and a light-shielding layer disposed on the bank layer and that includes a light-shielding opening that overlaps each of the light-sensing units. The plurality of light-emitting units include a first light-emitting unit disposed on one side of a light-sensing unit of the plurality of light-sensing units and a second light-emitting unit disposed on an opposite side of the light-sensing unit of the plurality of light-sensing units, and the light-shielding opening is located adjacent to the first light-emitting unit.

The light-shielding layer may further include a first light-emitting opening that overlaps the first light-emitting unit; and a second light-emitting opening that overlaps the second light-emitting unit. A minimum distance between the first light-emitting opening and the light-shielding opening differs from a minimum distance between the second light-emitting opening and the light-shielding opening.

The first light-emitting unit and the second light-emitting unit may be alternately arranged, and each of the light-sensing units is disposed between the first light-emitting unit and the second light-emitting unit.

The first light-emitting unit and the second light-emitting unit may emit a same color light.

The light-shielding opening may comprise a first light-shielding opening and a second light-shielding opening that overlaps one of the light-sensing units.

According to another embodiment of the disclosure, a display device includes a substrate, a light-emitting element disposed on the substrate and that includes a plurality of light-emitting units that emit light, a first electrode disposed on the substrate, a bank layer disposed on the substrate and that includes an opening that expos at least a part of the first electrode, a photoelectric conversion layer disposed on the first electrode exposed by the opening, and a light-shielding layer disposed on the photoelectric conversion layer and that includes a first light-shielding opening. The first light-shielding opening overlaps the bank layer.

The light-shielding layer may further comprise a second light-shielding opening adjacent to the first light-shielding opening.

The photoelectric conversion layer may include a first light-sensing unit and a second light-sensing unit that overlap the first electrode. The first light-sensing unit overlaps the first light-shielding opening, and the second light-sensing unit overlaps the second light-shielding opening.

The display device may further include a division bank layer that covers a part of an upper surface of the first electrode and partitions the first light-sensing unit and the second light-sensing unit. The photoelectric conversion layer is disposed on the upper surface of the first electrode in the first light-sensing unit and the second light-sensing unit.

The plurality of light-emitting units may include a first light-emitting unit adjacent to the first light-sensing unit; and a second light-emitting unit adjacent to the second light-sensing unit. The first light-shielding opening and the second light-shielding opening are located closer to the first light-emitting unit than to the second light-emitting unit.

The light-shielding layer may include a first light-emitting opening that overlaps the first light-emitting unit; and a second light-emitting opening that overlaps the second light-emitting unit. A minimum distance between the first light-emitting opening and the first light-shielding opening differs from a minimum distance between the second light-emitting opening and the second light-shielding opening.

The first light-emitting unit and the second light-emitting unit may be alternately arranged, and the first light-sensing unit and the second light-sensing unit are disposed between the first light-emitting unit and the second light-emitting unit.

The first light-shielding opening may overlap the bank layer, and the second light-shielding opening overlaps the division bank layer.

According to embodiments of the disclosure, a light-shielding opening is disposed adjacent to one side of the light-sensing unit, and a ratio of light that is totally reflected from a finger and is incident on the light-sensing unit through the light blocking opening can be increased. Since a sufficient amount of light can be received by a photo sensor while maintaining the light incident region or area on the light-sensing unit, the accuracy of fingerprint sensing can be increased.

### BRIEF DESCRIPTION OF THE DRAWINGS

FIG. 1 is a plan view of a display device according to an embodiment of the disclosure.

FIG. 2 is a block diagram of a display device according to an embodiment of the disclosure.

FIG. 3 shows a light incident region on a light-sensing unit of a display device according to an embodiment.

FIG. 4 is a graph of the light incident area on a light-sensing unit versus the light-sensing unit width of a display device according to an embodiment.

FIG. 5 is a plan view of a layout of pixels and photo sensors of a display panel according to an embodiment.

FIG. 6 is a cross-sectional view taken along line I-I′ of FIG. 5.

FIG. 7 is a schematic cross-sectional view of a display panel of FIG. 6.

FIG. 8 shows incident light in the cross-section of FIG. 7.

FIG. 9 illustrates an incidence range of light according to an embodiment.

FIG. 10 is a graph of the amount of light received by a photo sensor of a display panel versus the incident angle of the light according to an embodiment of the disclosure.

FIG. 11 is a circuit diagram of a pixel and a photo sensor of a display device according to an embodiment of the disclosure.

FIG. 12 is a plan view of pixels and photo sensors of a display panel according to an embodiment.

FIG. 13 is a cross-sectional view taken along line III-III′ of FIG. 12.

FIG. 14 is a schematic cross-sectional view of a display panel of FIG. 13.

FIG. 15 is a plan view of pixels and photo sensors of a display panel according to an embodiment.

FIG. 16 is a schematic cross-sectional view of a display panel, taken along line IV-IV′ of FIG. 15.

FIG. 17 is a plan view of pixels and photo sensors of a display panel according to an embodiment of the disclosure.

FIG. 18 is a cross-sectional view taken along line V-V′ of FIG. 17.

FIG. 19 is a schematic cross-sectional view of the display panel of FIG. 18.

FIG. 20 illustrates incident light in an example shown in FIG. 19.

### DETAILED DESCRIPTION

Embodiments of the present disclosure will now be described more fully hereinafter with reference to the accompanying drawings, in which embodiments are shown. Embodiments are provided so that this disclosure will be thorough and complete, and will filly convey the scope of the invention to those skilled in the art.

It will also be understood that when a layer is referred to as being “on” another layer or substrate, it can be directly on the other layer or substrate, or intervening layers may also be present. The same reference numbers may indicate the same components throughout the specification.

Hereinafter, embodiments of the disclosure will be described with reference to the accompanying drawings.

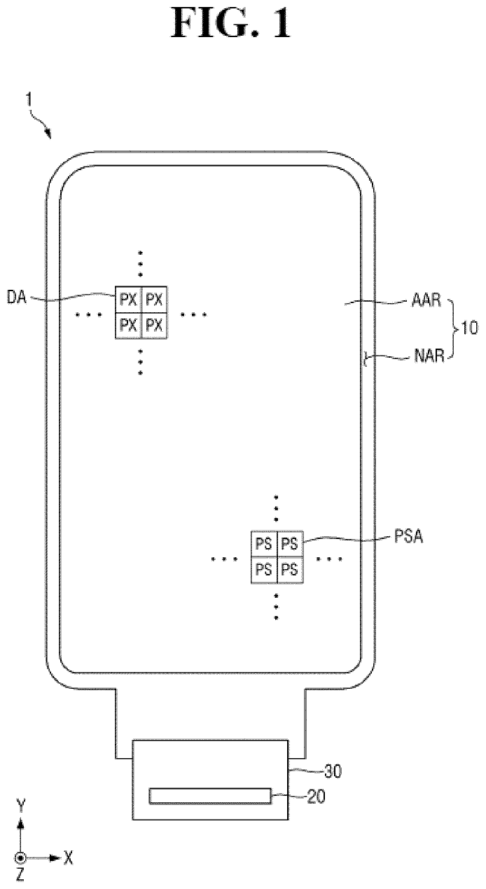

FIG. 1 is a plan view of a display device 1 according to an embodiment of the disclosure.

In FIG. 1, a first direction X, a second direction Y and a third direction Z are defined. The first direction X refers to a direction parallel to a first side of the display device 1, such as a horizontal direction of the display device 1 when viewed from the top. A second direction Y refers to a direction parallel to a second side of the display device 1 that meets the first side of the display device 1, such as a vertical direction of the display device 1 when viewed from the top. In the following description, for convenience of illustration, a first side in the first direction X indicates the right side, a second side in the first direction X indicates the left side, a first side in the second direction Y indicates the upper side, and a second side in the second direction Y indicates the lower side when viewed from the top. A third direction Z refers to the thickness direction of the display device 1, which is normal to a plane defined by the first direction X and the second direction Y. However, the directions referred to in the embodiments are relative directions, and embodiments are not limited to the directions mentioned.

Referring to FIG. 1, in an embodiment, the display device 1 may be any of a variety of electronic devices that include a display screen. Examples of the display device 1 include, but are not limited to, a mobile phone, a smart phone, a tablet PC, a mobile communications terminal, an electronic organizer, an e-book, a personal digital assistant (PDA), a portable multimedia player (PMP), a navigation device, an ultra-mobile PC (UMPC), a television set, a game machine, a wristwatch-type electronic device, a head-mounted display, a personal computer monitor, a laptop computer, a vehicle instrument cluster, a digital camera, a camcorder, an outdoor billboard, an electronic billboard, a medical apparatus, an inspection device, any of various home appliances that include a display area such as a refrigerator or a laundry machine, or an Internet of things (IoT) device, etc. Examples of the display device 1 to be described below include, but are not limited to, a smartphone, a tablet PC, a laptop computer, etc.

The display device 1 includes a display panel 10, a panel driver 20 and a circuit board 30.

The display panel 10 includes an active area AAR and a non-active area NAR. The active area AAR includes a display area DA where images are displayed. The active area AAR completely overlaps the display area DA. A plurality of pixels PX that display images are arranged in the display area DA. Each of the pixels PX includes a light-emitting element.

The active area AAR further includes a photo sensing area PSA. The photo sensing area PSA is a photosensitive area and senses incident light, wavelength, etc. The photo sensing area PSA overlaps the display area DA. According to an embodiment of the disclosure, the photo sensing area PSA is identical to the display area DA when viewed from the top and completely overlaps it. According to an embodiment, the photo sensing area PSA is disposed only in a part of the active area AAR. For example, the photo sensing area PSA is disposed only in a limited area for fingerprint recognition. In this example, the photo sensing area PSA overlaps a part of the display area DA but does not overlap other parts of the display area DA.

The photo sensing area PSA includes a plurality of photo sensors PS that react to light. Each of the photo sensors PS includes a photoelectric conversion element.

The non-active area NAR surrounds the active area AAR. The panel driver 20 is disposed in the non-active area NAR. The panel driver 20 drives the plurality of pixels PX and/or the plurality of photo sensors PS. The panel driver 20 outputs signals and voltages that drive the display panel 10. The panel driver 20 is implemented as an integrated circuit (IC) and is mounted on the display panel 10. Signal lines that transmit signals between the panel driver 20 and the active area AAR are further disposed in the non-active area NAR. For example, the panel driver 20 can be mounted on the circuit board 30.

The circuit board 30 is attached to one end of the display panel 10 using an anisotropic conductive film (ACF). Lead lines of the circuit board 30 are electrically connected to the pads of the display panel 10. The circuit board 30 may be a flexible printed circuit board (FPCB) or a flexible film such as a chip-on-film (COF).

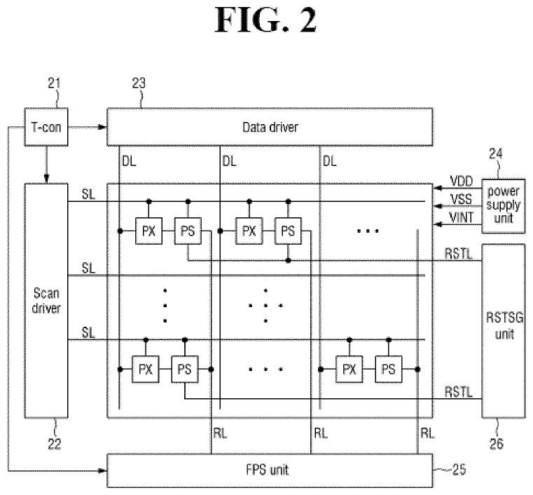

FIG. 2 is a block diagram of a display device according to an embodiment of the disclosure.

Referring to FIG. 2, in an embodiment, the plurality of pixels PX and the plurality of photo sensors PS disposed in the active area AAR of the display panel 10 are driven by the panel driver 20.

In the active area AAR of the display panel 10, scan lines SL connected to the plurality of pixels PX and the plurality of photo sensors PS, data lines DL connected to the plurality of pixels PX, and sensing lines RL and reset lines RSTL connected to the plurality of photo sensors PS, are disposed.

The panel driver 20 includes a scan driver 22 connected to the scan lines SL, a data driver 23 connected to the data lines DL, a power supply unit 24 that supplies a supply voltage, and a timing controller 21 that controls driving timings of the scan driver 22 and the data driver 23. The panel driver 20 is connected to pixels PX to adjust the amount of light emission, and drive the pixels PX to display images.

In addition, the panel driver 20 includes a fingerprint sensing unit (FPS unit) 25 connected to the sensing lines RL, and a reset signal generating unit (RSTSG unit) 26 connected to the reset lines RSTL. The panel driver 20 receives a current from each of the photo sensors PS to sense an external input.

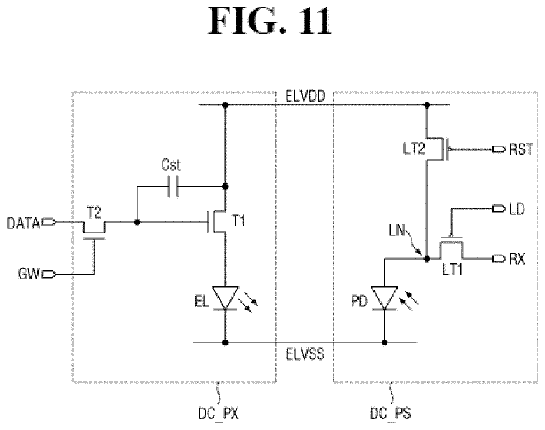

The scan driver 22 sequentially supplies scan signals GW, shown in FIG. 11, to the pixels PX connected to the scan lines SL based on a scan driving start signal received from the timing controller 21. The switching transistor of each of the pixels PX is turned on in response to the scan signal GW. The scan driver 22 also senses a fingerprint sensing signal LD, shown in FIG. 11, from the current flowing in the sensing lines RL in response to a sensing driving start signal from the timing controller 21. For example, a sensing transistor of the photo sensor PS is turned on based on the fingerprint sensing signal LD.

The data driver 23 supplies data signals DATA, shown in FIG. 11, for the pixels PX to the data lines DL based on a data driving start signal received from the timing controller 21.

The power supply unit 24 supplies supply voltages to each pixel PX and/or each photo sensor PS. The supply voltages include a first supply voltage VDD, a second supply voltage VSS and an initialization voltage VINT. The first supply voltage VDD is a high-level voltage that drives the light-emitting element and the photoelectric conversion element, and the second supply voltage VSS is a low-level voltage that drives the light-emitting element and the photoelectric conversion element. That is to say, the first supply voltage VDD has a higher level than the second supply voltage VSS.

The fingerprint sensing unit 25 senses a photocurrent through the sensing lines RL generated by each of the photo sensors PS. The fingerprint sensing unit 25 generates fingerprint sensing data based on the photocurrent received from each of the photo sensors PS and transmits it to a main processor. The main processor analyzes the fingerprint sensing data and determines whether it is identical to a user's fingerprint by comparison with a predetermined fingerprint.

The reset signal generating unit 26 generates a reset signal RST, shown in FIG. 11, based on a reset control signal received from the timing controller 21, and the reset signal RST is sequentially output to the reset lines RSTL. The reset signal RST is sequentially supplied to the photo sensors PS connected to the reset lines RSTL.

According to an embodiment of the disclosure, the scan lines SL are connected to both a plurality of pixels PX and a plurality of photo sensors PS. The plurality of pixels PX and the plurality of photo sensors PS can be turned on/off based on a same scan signal. Accordingly, the pattern of the fingerprint can be optically sensed while an image is displayed. However, embodiments are not limited thereto. In embodiments, the types and layout of the signal lines that include the scan lines SL, the data lines DL and the sensing lines RL varies depending on how the pixels PX and the plurality of photo sensors PS are driven.

Hereinafter, factors that determine a light incident area on the light-sensing unit of the display device according to an embodiment will be described.

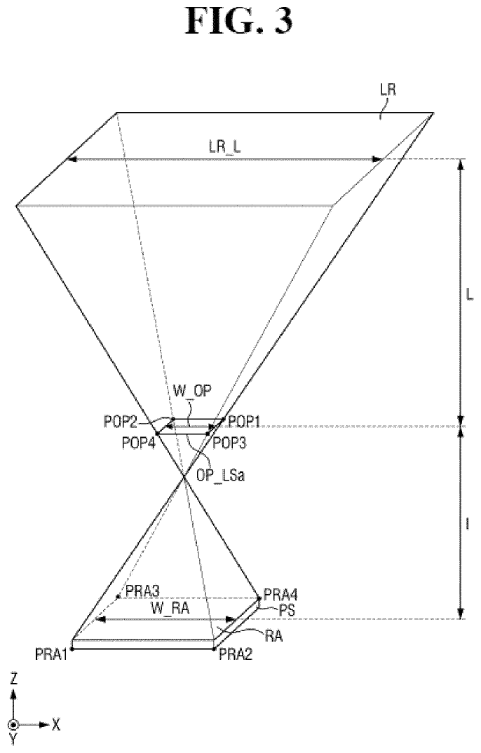

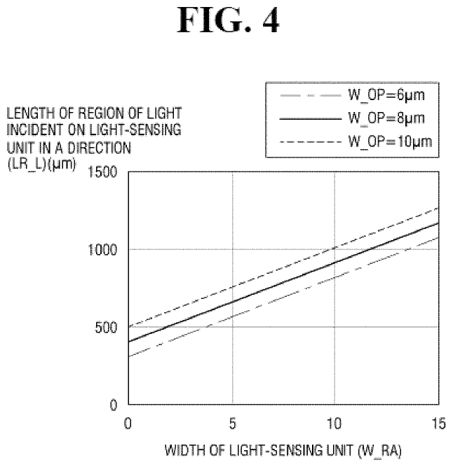

FIG. 3 illustrates a light incident region on a light-sensing unit of a display device according to an embodiment. FIG. 4 is a graph of light incident area on a light-sensing unit versus the light-sensing unit width of a display device according to an embodiment.

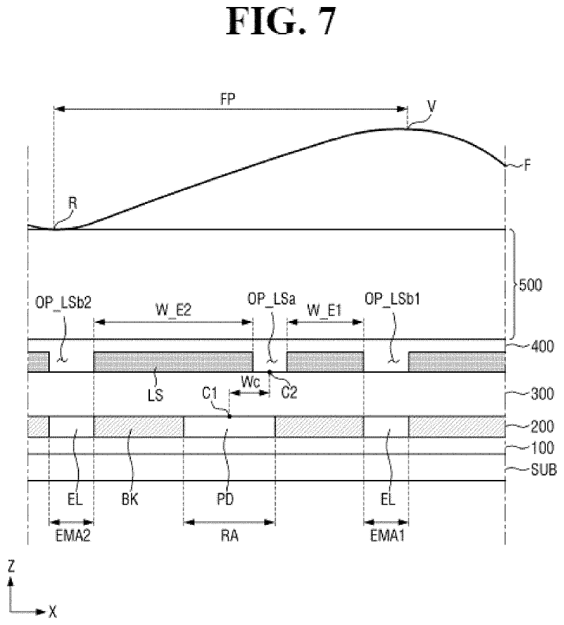

Referring to FIGS. 3 and 4, the smaller is the light incident region (or area) LR on each light-sensing unit RA, the smaller may be the area in which a fingerprint F, shown in FIG. 7, is acquired. As the area for acquiring the fingerprint F decreases, a ridge R, shown in FIG. 7, or a valley V, shown in FIG. 7, of the fingerprint can be more accurately detected, so that the accuracy of sensing a fingerprint increases.

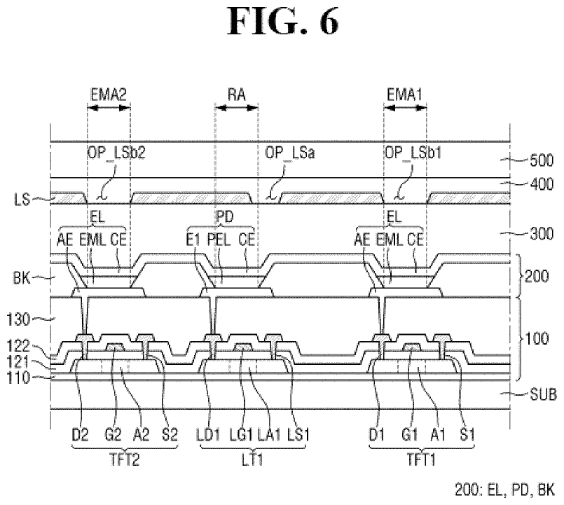

The light incident region LR on the light-sensing unit RA is determined by points at which the following lines meet the upper surface of a cover window 500, shown in FIG. 6. These lines include a line that connects a first vertex PRA1 of the upper surface of the light-sensing unit RA with a first vertex POP1 of the light-shielding opening OP_LSa, a line that connects a second vertex PRA2 of the upper surface of the light-sensing unit RA with a second vertex POP2 of the light-shielding opening OP_LSa, a line that connects a third vertex PRA3 of the upper surface of the light-sensing unit RA with a third vertex POP3 of the light-shielding opening OP_LSa, and a line that connects a fourth vertex PRA4 of the upper surface of the light-sensing unit RA with a fourth vertex POP4 of the light-shielding opening OP_LSa.

Therefore, the location of the light incident region LR on the light-sensing unit RA varies depending on a width W_RA of the light-sensing unit RA, a width W_OP of the light-shielding opening OP_LSa of the light-shielding layer LS, a distance L between the light-shielding layer LS and the cover window 500, and a distance l between the light-shielding layer LS and the photo sensor PS.

For example, the smaller is the width W_RA of the light-sensing unit RA, the smaller may be the light incident region LR on the light-sensing unit RA. For example, the smaller is the width W_OP of the light-shielding opening OP_LSa, the smaller may be the light incident region LR on the light-sensing unit RA. In addition, the smaller is the distance L between the light-shielding layer LS and the cover window 500 is, the smaller may be the light incident region LR on the light-sensing unit RA. The larger is the distance l between the light-shielding layer LS and the photo sensor, the smaller may be the light incident region LR on the light-sensing unit RA.

Referring to the graph of FIG. 4, for example, the light incident region LR on the light-sensing unit RA, or the length in the direction LR_L, when the width W_RA of the light-sensing unit RA is 10 μm or 5 μm, is smaller than when the width W_RA of the light-sensing unit RA is 15 μm. In addition, the light incident region LR on the light-sensing unit RA, or the length in the direction LR_L, when the width W_OP of the light-shielding opening OP_LSa is 8 μm or 6 μm, is smaller than when the width W_OP of the light-shielding opening OP_LSa is 10 μm. For example, the size or length in the direction LR_L of the light incident region LR on the light-sensing unit RA increases substantially linearly with the width W_RA of the light-sensing unit RA.

As the width W_RA of the light-sensing unit RA and the width W_OP of the light-shielding opening OP_LSa decrease, the size of the light incident the region LR on the light-sensing unit RA decreases, so that the accuracy of sensing fingerprint increases. However, the amount of light received by the photo sensors PS may decrease.

In the display device 1 according to an embodiment, the light-shielding opening OP_LSa is located adjacent to one side of the light-sensing unit RA while maintaining the width W_RA of the light-sensing unit RA and the width W_OP of the light-shielding opening OP_LSa. In this manner, the ratio of light that is totally reflected from the fingerprint F and is incident on the light-sensing unit RA through the light-shielding opening OP_LSa can be increased, so that a sufficient amount of light can be received. For example, a display device can be implemented that can ensure a high intensity of received light while maintaining the light incident the region LR on the light-sensing unit RA. For example, a display device can be implemented with high fingerprint sensing accuracy and increased received light intensity.

Hereinafter, a structure of a display panel according to an embodiment will be described in detail.

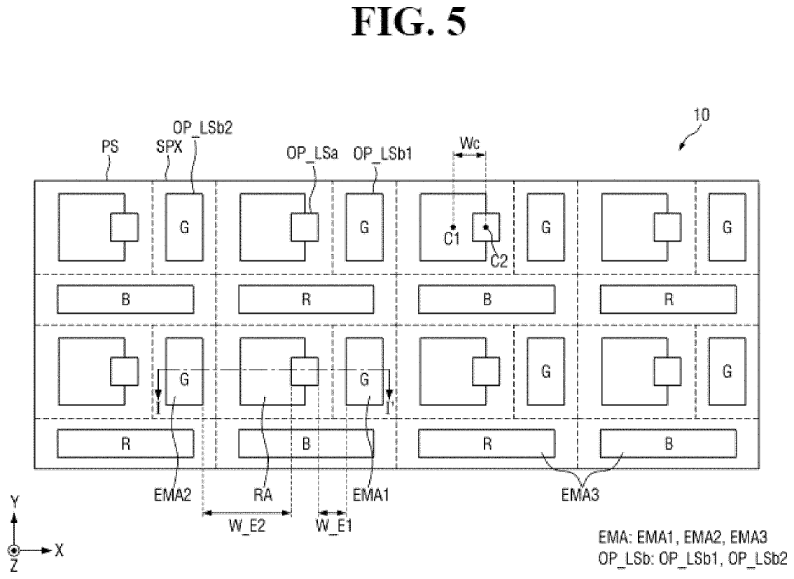

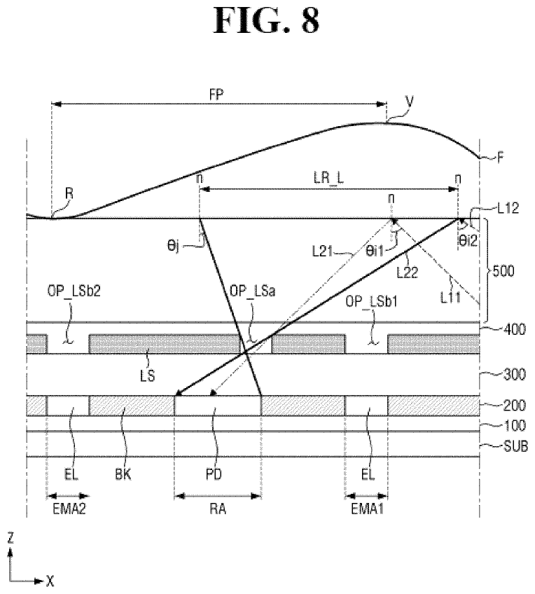

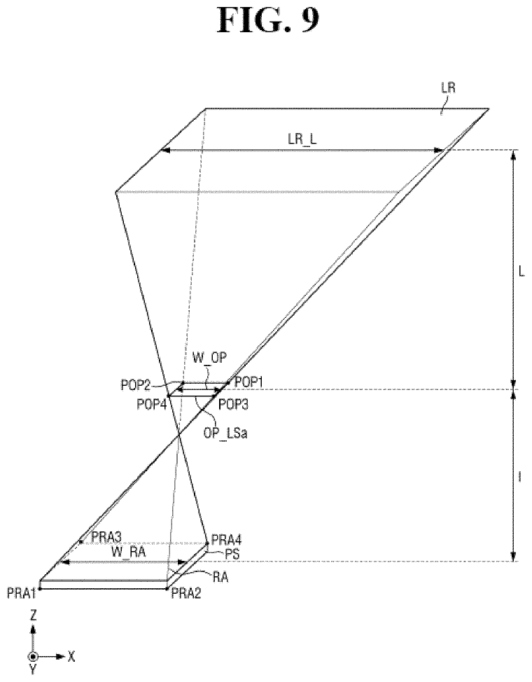

FIG. 5 is a plan view of a layout of pixels and photo sensors of a display panel according to another embodiment. FIG. 6 is a cross-sectional view taken along line I-I′ of FIG. 5. FIG. 7 is a schematic cross-sectional view of the display panel, taken along line I-I′ of FIG. 5. FIG. 8 shows incident light in the cross section shown in FIG. 7. FIG. 9 shows an incidence range of light according to an embodiment.

Referring to FIGS. 5 and 6, in an embodiment, each of the plurality of pixels PX disposed on the display panel 10 includes a plurality of sub-pixels SPX. Each of the sub-pixels SPX includes a light-emitting unit EMA in the display area DA that emits light. Each of the plurality of light-emitting units EMA include a pixel electrode AE exposed by an opening of a bank layer BK where the exposed pixel electrode AE and an emissive layer EML overlap each other.

In addition, a plurality of photo sensors PS are disposed in the light sensing area PSA that overlap the display area DA of the pixel PX. Each of the plurality of photo sensors PS includes a light-sensing unit RA in the light sensing area PSA that senses light. The light-sensing unit RA includes a first electrode E1 exposed by the opening of the bank layer BK where the exposed first electrode E1 and a photoelectric conversion layer PEL overlap each other.

Hereinafter, the arrangement relationship between the plurality of sub-pixels SPX and the plurality of photo sensors PS will be described.

Each of the plurality of sub-pixels SPX disposed on the display panel 10 includes a green light-emitting unit, a red light-emitting unit, and a blue light-emitting unit. The light-emitting units EMA are arranged in a matrix.

According to an embodiment of the disclosure, the green light-emitting units G are arranged in the first direction X and form a first row while the red light-emitting units R and the blue light-emitting units B are alternately arranged in the first direction X and form a second row adjacent to the first row. The pixels PX of the first row are staggered in the first direction X with respect to the pixels PX of to the second row. The number of green light-emitting units G in the first row is twice the number of red light-emitting units R or blue light-emitting units B in the second row. The first row and the second row may be repeatedly arranged up to an n^{th} row.

In addition, the blue light-emitting units B and the red light-emitting units R are alternately arranged in the second direction Y and form a first column while the green light-emitting units G are arranged and spaced apart in the second direction Y and form a second column adjacent to the first column. The red light-emitting units R and the blue light-emitting units B are alternately arranged in a third column adjacent thereto, and the green light-emitting units G are arranged and spaced apart in the first direction X in a fourth column adjacent thereto. The light-emitting units EMA may be repeatedly arranged in this manner up to an n^{th} column.

Different light-emitting units EMA have different areas. For example, the green light-emitting units G are smaller than the red light-emitting units R and the blue light-emitting units B. Although the light-emitting units EMA may have a rectangular or square shape when viewed from the top, embodiments of the disclosure are not limited thereto. In other embodiments, the light-emitting units EMA have other shapes, such as an octagon, a circle or a diamond.

When the plurality of photo sensors PS are disposed in the light sensing area PSA that overlaps the display area DA, the light-sensing unit RA is disposed between the green light-emitting units G.

For example, the green light-emitting units G and the light-sensing units RA are alternately arranged in the first direction Xin the green rows. The red light-emitting units R and the blue light-emitting units B are alternately arranged in the first direction X in the red-blue rows.

Referring to FIGS. 5 and 7, in an embodiment, the light-shielding layer LS includes a light-shielding opening OP_LSa and a light-emitting opening OP_LSb respectively disposed on and overlapping the light-sensing units RA and the light-emitting units EMA. The light-shielding opening OP_LSa overlaps each of the light-sensing units RA and allows light L21 and L22, shown in FIG. 8, incident on the light-sensing units RA to pass therethrough in the third direction Z. In addition, the light-emitting opening OP_LSb overlaps each of the light-emitting units EMA and allows light L11 and L12, shown in FIG. 8, emitted from the light-emitting units EMA to pass therethrough in the third direction Z. The width of the light-shielding opening OP_LSa in the first direction X is less than the width of the light-emitting opening OP_LSb in the first direction X. Although in the following description the light-emitting opening OP_LSb has substantially the same width as the light-emitting units EMA, embodiments are not limited thereto, and the light-emitting opening OP_LSb may have a width greater than the width of the light-emitting units EMA. For example, the light-shielding layer LS does not overlap the light-emitting units EMA.

The light-shielding opening OP_LSa is located adjacent to one side of each of the light-sensing units RA. The one side may be, but is not limited to, the side in the first direction X or the second direction Y. The center C1 of the light sensing area RA is spaced apart from the center C2 of the light-shielding opening OP_LSa by a distance Wc.

Accordingly, at least a part of the light-shielding opening OP_LSa overlaps each of the light-sensing units RA, but at least another part of the light-shielding opening OP_LSa overlaps the bank layer BK. For example, at least another part of the light-shielding opening OP_LSa does not overlap the light-sensing units RA.

According to an embodiment, among the green light-emitting units G, the red light-emitting units R and the blue light-emitting units B in each sub-pixel SPX, the light-emitting unit disposed on one side of the light sensing area RA in the first direction X is referred to as a first light-emitting unit EMA1, while the light-emitting unit disposed on the opposite side of the light sensing area RA in the first direction X is referred to as a second light-emitting unit EMA2. The other light-emitting units are referred to as third light-emitting units EMA3.

The light-shielding opening OP_LSa is located closer to the first light-emitting unit EMA1 than to the second light-emitting unit EMA2.

The light-emitting opening OP_LSb of the light blocking layer LS further includes a first light-emitting opening OP_LSb1 that overlaps the first light-emitting unit EMA1 and a second light-emitting opening OP_LSb2 that overlaps the second light-emitting unit EMA2.

The minimum distance between the first light-emitting opening OP_LSb1 and the light-shielding opening OP_LSa is defined as a first distance W_E1, and the minimum distance between the second light-emitting opening OP_LSb2 and the light-shielding opening OP_LSa is defined as a second distance W_E2. The first distance W_E1 differs from the second distance W_E2. More specifically, the first distance W_E1 is less than the second distance W_E2.

In addition, the difference between the first distance W_E1 and the second distance W_E2 is greater than the distance Wc between the center C1 of the light-sensing units RA and the center C2 of the light-shielding opening OP_LSa. For example, the difference between the first distance W_E1 and the second distance W_E2 is greater than twice the distance Wc between the center C1 of the light-sensing units RA and the center C2 of the light-shielding opening OP_LSa. However, embodiments of the disclosure are not limited thereto.

In the display device 1, the light-shielding opening OP_LSa is located adjacent to one side of each of the light-sensing units RA, and the ratio of light that is totally reflected from the fingerprint F and is incident on the light-sensing unit RA through the light-shielding opening OP_LSa is increased. Accordingly, the intensity of received light in the display device 1 is increased.

The cross section of each pixel PX and light-emitting unit EMA and each photo sensor PS and light-sensing unit RA will be described with reference to FIG. 6.

Referring to FIG. 6, in an embodiment, the display panel 10 includes a substrate SUB, a thin-film transistor layer 100 disposed on the substrate SUB, a light-emitting element layer 200 disposed on the thin-film transistor layer 100, an encapsulation layer 300 disposed on the light-emitting element layer 200, a light-shielding layer LS disposed on the encapsulation layer 300, an overcoat layer 400 that covers the light-shielding layer LS, and a cover window 500 disposed on the overcoat layer 400.

The substrate SUB supports the layers disposed thereon. The substrate SUB is made of an insulating material such as a polymer resin. Examples of a polymer material include polyethersulphone (PES), polyacrylate (PA), polyacrylate (PAR), polyetherimide (PEI), polyethylene naphthalate (PEN), polyethylene terephthalate (PET), polyphenylene sulfide (PPS), polyallylate, polyimide (PI), polycarbonate (PC), or a combination thereof.

The thin-film transistor layer 100 is disposed on the substrate SUB. The thin-film transistor layer 100 includes a first thin-film transistor TFT1, a second thin-film transistor TFT2, a first sensing transistor LT1, a buffer layer 110, a gate insulating layer 121, an interlayer dielectric film 122, and a planarization layer 130, etc.

The buffer layer 110 is disposed on the substrate SUB. The buffer layer 110 includes at least one of silicon nitride (SiNx), silicon oxide (SiOx), or silicon oxynitride.

The first thin-film transistor TFT1, the second thin-film transistor TFT2 and the first sensing transistor LT1 are formed of a thin-film transistor and are disposed on the buffer layer 110.

The plurality of thin-film transistors TFT1, TFT2 and LT1 respectively include semiconductor layers A1, A2 and LA1, a gate insulating layer 121 disposed on a part of the buffer layer 110 and that covers the semiconductor layers A1, A2 and LA1; gate electrodes G1, G2 and LG1 disposed on the gate insulating layer 121; an interlayer dielectric film 122 disposed on the gate insulating layer 121 and that covers the gate electrodes G1, G2 and LG1, and source electrodes S1, S2 and LS1 and drain electrodes D1, D2 and LD1 disposed on the interlayer dielectric film 122.

The semiconductor layers A1, A2 and LA1 form the channels of the first thin-film transistor TFT1, the second thin-film transistor TFT2 and the first sensing transistor LT1, respectively. The semiconductor layers A1, A2 and LA1 include polycrystalline silicon. According to an embodiment, the semiconductor layers A1, A2 and LA1 include at least one of monocrystalline silicon, low-temperature polycrystalline silicon, amorphous silicon, or an oxide semiconductor. The oxide semiconductor includes, for example, at least one of a binary compound (ABx), a ternary compound (ABxCy) or a quaternary compound (ABxCyDz) that contains one or more of indium, zinc, gallium, tin, titanium, aluminum, hafnium (Hf), zirconium (Zr), or magnesium (Mg), etc. Each of the semiconductor layers A1, A2 and LA1 includes a channel region, and a source region and a drain region doped with impurities.

The gate insulating layer 121 is disposed on the buffer layer 110 and covers the semiconductor layers A1, A2 and LA1. The gate insulating layer 121 electrically insulates the first gate electrode G1 from the first semiconductor layer A1, the second gate electrode G2 from the second semiconductor layer A2, and the first sensing gate electrode LG1 from the first sensing semiconductor layer LA1. The gate insulating layer 121 is made of an insulating material, such as silicon oxide (SiOx), silicon nitride (SiNx), or a metal oxide, etc.

The first gate electrode G1 of the first thin-film transistor TFT1, the second gate electrode G2 of the second thin-film transistor TFT2, and the first sensing gate electrode LG1 of the first sensing transistor LT1 are disposed on the gate insulating layer 121. The gate electrodes G1, G2 and LG1 are disposed on the gate insulating layer 121 above the channel regions of the semiconductor layers A1, A2 and LA1, respectively, and overlap the channel regions.

The interlayer dielectric film 122 is disposed on the gate insulating layer 121 and covers the gate electrodes G1, G2 and LG1. The interlayer dielectric film 122 includes inorganic insulating materials such as silicon oxide (SiOx), silicon nitride (SiNx), silicon oxynitride, hafnium oxide or aluminum oxide. In addition, the interlayer dielectric film 122 may include a plurality of insulating films, and may further include a conductive layer that forms a second electrode of a capacitor between the insulating films.

The source electrodes S1, S2 and LS1 and the drain electrodes D1, D2 and LD1 are disposed on the interlayer dielectric film 122. The first source electrode S1 of the first thin-film transistor TFT1 is electrically connected to the source region of the first semiconductor layer A1 through a contact hole that penetrates the interlayer dielectric film 122 and the gate insulating layer 121. The second source electrode S2 of the second thin-film transistor TFT2 is electrically connected to the source region of the second semiconductor layer A2 through a contact hole that penetrates the interlayer dielectric film 122 and the gate insulating layer 121. The first sensing source electrode LS1 of the first sensing thin-film transistor LT1 is electrically connected to the source region of the first sensing semiconductor layer LA1 through a contact hole that penetrates the interlayer dielectric film 122 and the gate insulating layer 121. Similarly, the first drain electrode D1 of the first thin-film transistor TFT1 is electrically connected to the drain region of the first semiconductor layer A1 through a contact hole that penetrates the interlayer dielectric film 122 and the gate insulating layer 121. The second drain electrode D2 of the second thin-film transistor TFT2 is electrically connected to the drain region of the second semiconductor layer A2 through a contact hole that penetrates the interlayer dielectric film 122 and the gate insulating layer 121. The first sensing drain electrode LD1 of the first sensing thin-film transistor LT1 is electrically connected to the drain region of the first sensing semiconductor layer LA1 through a contact hole that penetrates the interlayer dielectric film 122 and the gate insulating layer 121. The source electrodes S1, S2 and LS1 and the drain electrodes D1, D2 and LD1 include at least one of aluminum (Al), molybdenum (Mo), platinum (Pt), palladium (Pd), silver (Ag), magnesium (Mg), gold (Au), nickel (Ni), neodymium (Nd), iridium (Ir), chromium (Cr), calcium (Ca), titanium (Ti), tantalum (Ta), tungsten (W) or copper (Cu).

The planarization layer 130 is disposed on the interlayer dielectric film 122 and covers the source electrodes S1, S2 and LS1 and the drain electrodes D1, D2 and LD1. The planarization layer 130 is made of an organic insulating material, etc. The planarization layer 130 has a flat upper surface and includes contact holes that expose the drain electrodes D1, D2 and LD1, respectively.

The light-emitting element layer 200 is disposed on the planarization layer 130. The light-emitting element layer 200 includes a light-emitting element EL, a photoelectric conversion element PD, and a bank layer BK. The light-emitting element EL includes a pixel electrode AE, an emissive layer EML, and a common electrode CE. The photoelectric conversion element PD includes a first electrode E1, a photoelectric conversion layer PEL, and a common electrode CE.

The pixel electrode AE of the light-emitting element EL is disposed on the planarization layer 130. The pixel electrode AE is provided for each pixel PX. The pixel electrode AE is connected to the first source electrode S1 or the first drain electrode D1 of the first thin-film transistor TFT1 and is connected to the second source electrode S2 or the second drain electrode D2 of the second thin-film transistor TFT2 through a contact hole that penetrates through the planarization layer 130.

The pixel electrode AE of the light-emitting element EL may have, but is not limited to, a single-layer structure of molybdenum (Mo), titanium (Ti), copper (Cu) or aluminum (Al), or may have stack of multiple films, such as a multi-layer structure of ITO/Mg, ITO/MgF, ITO/Ag or ITO/Ag/ITO that includes indium-tin-oxide (ITO), indium-zinc-oxide (IZO), zinc oxide (ZnO), or indium oxide (In₂O₃), and silver (Ag), magnesium (Mg), aluminum (Al), platinum (Pt), lead (Pd), gold (Au) or nickel (Ni).

The first electrode E1 of the photoelectric conversion element PD is also disposed on the planarization layer 130. The first electrode E1 is disposed for each of the photo sensors PS. The first electrode E1 is connected to a first sensing source electrode LS1 or a first sensing drain electrode LD1 of the first sensing transistor LT1 through a contact hole that penetrates through the planarization layer 130.

The first electrode E1 of the photoelectric conversion element PD may have, but is not limited to, a single-layer structure of molybdenum (Mo), titanium (Ti), copper (Cu) or aluminum (Al), or a multi-layer structure of ITO/Mg, ITO/MgF, ITO/Ag or ITO/Ag/ITO.

The bank layer BK is disposed on the planarization layer 130, the pixel electrode AE and the first electrode E1. The bank layer BK includes openings that overlap the pixel electrode AE that expose the pixel electrodes AE and the emissive layer EML. The areas where the exposed pixel electrode AE and the emissive layer EML overlap each other are defined as the plurality of light-emitting units EMA that include the first light-emitting unit EMA1 and the second light-emitting unit EMA2. In addition, the bank layer BK includes openings that overlap the first electrode E1 expose the first electrode E1 and the photoelectric conversion layer PEL. The openings that expose the first electrode E1 provide a space in which the photoelectric conversion layer PEL of each of the photo sensors PS is formed, and the area where the exposed first electrode E1 and the photoelectric conversion layer PEL overlap each other is defined as the light-sensing unit RA.

The bank layer BK includes an organic insulating material, such as polyacrylate resin, epoxy resin, phenolic resin, polyamide resin, polyimide resin, unsaturated polyesters resin, poly phenylen ether resin, poly phenylene sulfide resin, or benzocyclobutene (BCB). In an embodiment, the bank layer BK includes an inorganic material such as silicon nitride.

The emissive layer EML is disposed on the pixel electrode AE of the light-emitting element EL exposed by the opening of the bank layer BK. The emissive layer EML includes a high-molecular weight material or a low-molecular weight material, and emits one of red, green or blue light from the sub-pixel SPX in each pixel PX. The light emitted from the emissive layer EML contributes to forming an image or functions as a light source incident on the photo sensor PS.

When the emissive layer EML is formed of an organic material, a hole injecting layer HIL and a hole transporting layer HTL are disposed under each emissive layer EML, and an electron injecting layer EIL and an electron transporting layer ETL are disposed above each emissive layer EML. These may have a single-layer or multi-layer structure that includes an organic material.

The first light-emitting unit EMA1 of the light-emitting element EL disposed on one side of the light-sensing unit RA in the first direction X emits a first light, and the second light-emitting unit EMA2 of the light-emitting element EL disposed on the opposite side of the light-sensing unit RA in the first direction X emits a second light. The first light and the second light may each be, but are not limited to, a green light.

The photoelectric conversion layer PEL is disposed on the first electrode E1 of the photoelectric conversion element PD exposed by the opening of the bank layer BK. The photoelectric conversion layer PEL generates photocharges in proportion to the intensity of the incident light. The incident light may be light that was emitted from the emissive layer EML and was reflected into the photoelectric conversion layer PEL, or may be light received from the outside. Charges generated and accumulated in the photoelectric conversion layer PEL are converted into electrical signals required for sensing. When the photoelectric conversion element PD is exposed to external light, the photoelectric conversion layer PEL generates photocharges in proportion to the intensity of light to which it is exposed.

The photoelectric conversion layer PEL includes electron donors and electron acceptors. The electron donors generate donor ions in response to light, and the electron acceptors generate acceptor ions in response to light. When the photoelectric conversion layer PEL is formed of an organic material, the electron donors include, but are not limited to, a compound such as subphthalocyanine (SubPc) or dibutylphosphate (DBP). The electron acceptors include, but are not limited to, a compound such as fullerene, a fullerene derivative, or perylene diimide.

Alternatively, when the photoelectric conversion layer PEL is formed of an inorganic material, the photoelectric conversion element PD is a p-n junction or a pin-type phototransistor. For example, the photoelectric conversion layer PEL has a structure in which an n-type semiconductor layer, an i-type semiconductor layer, and a p-type semiconductor layer are sequentially stacked on each other.

When the photoelectric conversion layer PEL is formed of an organic material, a hole injecting layer HIL and a hole transporting layer HTL are disposed under each photoelectric conversion layer PEL, and an electron injecting layer EIL and an electron transporting layer ETL are disposed above each photoelectric conversion layer PEL. These may have a single-layer or multi-layer structure that includes an organic material.

The light-sensing unit RA is an area that receives light that has the same wavelength as the light emitted from the light-emitting units EMA of the adjacent light-emitting element EL as a light source.

Although the areas where the emissive layer EML and the photoelectric conversion layer PEL are disposed are substantially identical to those of the light-emitting units EMA and the light-sensing unit RA, respectively, in the foregoing description, the emissive layer EML may cover the bank layer BK beyond the light-emitting units, and the photoelectric conversion layer PEL may cover the bank layer BK beyond the photo sensing unit RA.

The common electrode CE is disposed on the emissive layer EML, the photoelectric conversion layer PEL and the bank layer BK. The common electrode CE is disposed across the plurality of sub-pixels SPX and the photo sensors PS such that it covers the emissive layer EML, the photoelectric conversion layer PEL and the bank layer BK. The common electrode CE includes a conductive material that has a low work function, such as Li, Ca, LiF/Ca, LiF/Al, Al, Mg, Ag, Pt, Pd, Ni, Au, Nd, Ir, Cr, BaF, or B a, or a compound or mixture thereof, such as a mixture of Ag and Mg). Alternatively, the common electrode CE includes a transparent metal oxide, such as indium-tin-oxide (ITO), indium-zinc-oxide (IZO), or zinc oxide (ZnO), etc.

Although embodiments are not limited thereto, the photoelectric conversion element PD and the light-emitting element EL share the common electrode CE disposed on the photoelectric conversion layer PEL and the emissive layer EML.

The encapsulation layer 300 is disposed on the light-emitting element layer 200. The encapsulation layer 300 includes at least one inorganic film that prevents permeation of oxygen or moisture into each of the emissive layer EML and the photoelectric conversion layer PEL. In addition, the encapsulation layer 300 includes at least one organic film that protects the emissive layer EML and the photoelectric conversion layer PEL from particles such as dust. For example, the encapsulation layer 300 has a structure in which a first inorganic film, an organic film, and a second inorganic film are sequentially stacked on each other. The first inorganic film and the second inorganic film include multiple films in which one or more inorganic films of a silicon nitride layer, a silicon oxynitride layer, a silicon oxide layer, a titanium oxide layer or an aluminum oxide layer are alternately stacked on each other. The organic film is one of an acryl resin, an epoxy resin, a phenolic resin, a polyamide resin or a polyimide resin.

A light-shielding layer LS is disposed on the encapsulation layer 300. In an embodiment, when a touch layer is further disposed on the encapsulation layer 300, the light-shielding layer LS may be disposed between the encapsulation layer 300 and the touch layer or may be disposed on the touch layer. The position of the light-shielding layer LS is not particularly limited as long as it is disposed on the encapsulation layer 300.

The light-shielding layer LS is made of a material that blocks light emission from the light-emitting element EL. The light-shielding layer LS forms a black matrix using a material that absorbs visible light, such as a metal or a resin that includes a pigment such as carbon black or a dye. In an embodiment, the light-shielding layer LS has a stack structure of a red color filter, a green color filter and a blue color filter. Accordingly, the light-shielding layer LS can prevent color mixing between the sub-pixels SPX.

As described above, the light-shielding layer LS has a plurality of light-emitting openings OP_LSb1 and OP_LSb2 and a plurality of light-shielding openings OP_LSa that transmit light. The first light-emitting opening OP_LSb1 overlaps the first light-emitting unit EMA1 and passes light emitted in the third direction Z from the light-emitting element EL disposed on the first light-emitting unit EMA1. The second light-emitting opening OP_LSb2 overlaps the second light-emitting unit EMA2 and passes light emitted in the third direction Z from the light-emitting element EL disposed on the second light-emitting unit EMA2. In addition, each of the plurality of light-shielding openings OP_LSa overlaps the light-sensing unit RA to allow light incident on the photoelectric conversion element PD in the direction opposite to the third direction Z to pass therethrough.

The light-shielding layer LS is covered by the overcoat layer 400. The overcoat layer 400 is made of a material that can transmit light. The overcoat layer 400 provides a flat surface over the light-shielding layer LS. The overcoat layer 400 may be made of, but is not limited to, an acrylic epoxy.

The cover window 500 is disposed on the overcoat layer 400. The cover window 500 protects the configuration of the display device 1. The cover window 500 may be made of glass or plastic. When the cover member includes glass, a flexible ultra-thin glass (UTG) that has a thickness of 0.1 mm or less is used. In addition, a polarizing plate may be disposed between the cover window 500 and the overcoat layer 400.

Referring to FIGS. 8 and 9, in an embodiment, the fingerprint F of a finger includes alternating ridges R and valleys V in a unique pattern. When the fingerprint F is in contact with the upper surface of the cover window 500, the ridges R of the fingerprint F are in contact with the upper surface of the cover window 500, while the valleys V of the fingerprint F are not in contact with the upper surface of the cover window 500. That is to say, the upper surface of the cover window 500 is in contact with air where valleys V are located.

When the fingerprint F is in contact with the upper surface of the cover window 500, light output from the light-emitting element EL may be reflected off the ridges R and valleys V of the fingerprint F. Since the refractive index of the fingerprint F differs from the refractive index of air, the amount of light reflected off the ridges R of the fingerprint F differs from the amount of light reflected from the valleys V. Accordingly, the ridges R and the valleys V of the fingerprint F can be determined based on a difference in the intensity of reflected light, i.e., the light incident on the photoelectric conversion element PD. Since the photoelectric conversion element PD outputs an electrical signal according to the difference in light, the pattern of the fingerprint F of the finger can be identified.

The length LR_L of the light incident region or area LR on the light-sensing unit RA in a direction may be shorter than the distance FP between the ridge R and the valley V of the fingerprint F. The direction may be, but is not limited to, the first direction X or the second direction Y.

The light emitted from the light-emitting element EL passes through the cover window 500 and exits through the upper surface of the cover window 500.

Among the lights L11 and L12 emitted from the light-emitting elements EL, at least some of the lights L21 and L22 are reflected toward the photoelectric conversion element PD from the interface between the upper surface of the cover window 500 and air or from the interface between the upper surface of the cover window 500 and the ridges R of the fingerprint F. When the incident angle of the light emitted from the light-emitting elements EL and incident on the interface is equal to or greater than the critical angle, the light is totally reflected from the upper surface of the cover window 500. The incident angle of the light emitted from the light-emitting element EL and incident on the interface refers to an angle formed by the normal line n that is perpendicular to the upper surface of the cover window 500 and the incident light.

The critical angle varies depending on the refractive index of the cover window 500 and the refractive index of the medium, air or fingerprint F, in contact with the upper surface of the cover window 500. For example, when the refractive index of the cover window 500 has a value of 1.4 to 1.6 and the medium in contact with the upper surface of the cover window 500 is air, the critical angle ranges from 35° to 50°.

In FIG. 8, in an embodiment, a first total reflection angle θi1 is the critical angle, and the second total reflection angle θi2 is the maximum total reflection angle within the light incident region or area LR on the light-sensing unit RA. In this instance, the first total reflection angle θi1 is smaller than the second total reflection angle θi2. In addition, a first incident angle θj has a largest absolute value in the negative (−) direction of light incident on the light-sensing unit RA from the light-shielding opening OP_LS.

The light L11 emitted from the light-emitting element EL that has the first total reflection angle θi1 is totally reflected at the interface of the cover window 500. The reflected light L21 is incident on the light-sensing unit RA. In addition, the light L12 emitted from the light-emitting element EL that has the second total reflection angle θi2 is totally reflected at the interface of the cover window 500. The reflected light L22 is incident on the light-sensing unit RA.

In this instance, the length LR_L of the light incident region or area LR on the light-sensing unit RA is determined by the light incident at the first incident angle θj and the light L22 reflected at the second total reflection angle θi2.

In particular, the light incident region or area LR on the light-sensing unit RA receives a high amount of light where the totally reflected light at the first total reflection angle θi1 and the second total reflection angle θi2 are collected.

For example, when the light-shielding opening OP_LSa is disposed closer to the first light-emitting opening OP_LSb1 than to the second light-emitting opening OP_LSb2, the amount of light L11 and L12 totally reflected into light L21 and L22 at the interface of the cover window 500 increases. For example, the amount of light L11 and L12 emitted from the light-emitting element EL and incident on the interface at an angle greater than the critical angle increases.

Even in this instance, the width W_RA of the light-sensing unit RA and the width W_OP of the light-shielding opening OP_LSa are constant, and thus the length LR_L of the light incident region or area LR on the light-sensing unit RA, which is defined by the reflected light L21 and the reflected light L22, is also constant.

In a display device according to an embodiment of the disclosure, even without decreasing the width W_RA of the light-sensing unit RA and the width W_OP of the light-shielding opening OP_LSa, the minimum light incident region LR can be maintained on the light-sensing unit RA that can distinguish between the ridges R and the valleys V of the fingerprint F. A display device can received a high amount of light because the amount of light that is totally reflected and incident on the light-sensing unit RA increases.

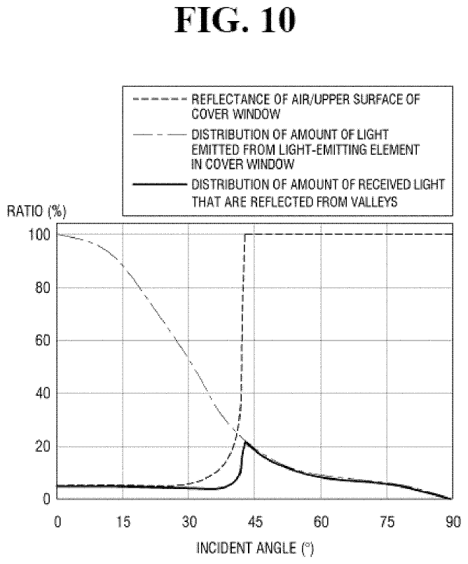

FIG. 10 is a graph of the intensity of light received by a photo sensor of a display panel versus the incident angle of the light according to an embodiment of the disclosure.

In FIG. 10, the x-axis represents an angle at which light emitted from the light-emitting element EL is incident on the interface between the cover window 500 and air or the interface between the cover window 500 and a ridge R, and the y-axis axis represents a ratio of light emitted from the light-emitting element EL that is totally reflected at the interface.

Referring to FIG. 10, in an embodiment, when the angle of light emitted from the light-emitting element EL and incident on the interface or the upper surface of the cover window 500 exceeds 30°, the intensity of light that is totally reflected at the interface or the upper surface of the cover window 500 increases. That is to say, FIG. 10 shows an example where the total reflection critical angle is 30°. In particular, all of the light incident on the interface or the upper surface of the cover window 500 at an angle of 44° or greater is reflected.

The amount of light emitted from the light-emitting element EL and reaching the interface decreases as the incident angle on the interface increases. For example, the amount of light reaching the interface at an angle of 44° is approximately 20% of the amount of light reaching the interface at an incident angle of 0°.

However, since all light is totally reflected when the incident angle is 44° or greater, the amount of light incident on the photo sensor PS increases at an incident angle of 44° or greater.

Hereinafter, a design that can increase the amount of light incident on the photo sensor PS using totally reflected light will be described in detail in conjunction with Table 1.

TABLE 1

| | | | | | | Increase In |
|---|---|---|---|---|---|---|
| | | | | | | Amount Of |
| Width W_RA of | | Wc = 0 um | | Wc = 6.5 um | | Received |
| Light-sensing | | Incident | | Incident | | Light (%) |
| unit RA | | Angle (°) | LR_L(μm) | Angle (°) | LR_L(μm) | 18.7 |
| 7 | μm | −27.3~27.3 | 600.9 | 0~45.9 | 594.9 | 18.7 |
| 10 | μm | −32.4~32.4 | 738.2 | −6.8~49.0 | 733.7 | 36.2 |
| 13 | μm | −37.0~37.0 | 875.5 | −13.4~51.8 | 872.5 | 43.3 |

It can be seen from Table 1 that, given an incident angle as a function of the width W_RA of the light-sensing unit RA and the length LR_L of the light incident region or area LR on the light-sensing unit RA, and the amount of received light increases as the distance Wc between the center C1 of the light-sensing unit RA and the center C2 of the light-shielding opening OP_LSa changes from 0 μm to 6.5 μm.

When the distance Wc between the center C1 of the light-sensing unit RA and the center C2 of the light-shielding opening OP_LSa is 0 μm, the incident angle of the light emitted from the light-emitting element EL exceeds the critical angle of total reflection, which is about 35 to 50°, only when the width W_RA of the light-sensing unit RA is 13 μm or more. On the other hand, when the distance Wc between the center C1 of the light-sensing unit RA and the center C2 of the light-shielding opening OP_LSa is approximately 6.5 μm, the amount of reflected light that has an incident angle that exceeds the critical angle of total reflection increases.

For example, an incident or reflected light that has an incident angle that exceeds the critical angle is totally reflected at the interface of the cover window 500, and as the amount of totally reflected, incident light increases, the amount of light received by the photo sensor PS increases. Even in this instance, the light incident region or area LR on the light-sensing unit RA maintains the minimum value for accurately sensing fingerprints.

FIG. 11 is a circuit diagram of a pixel and a photo sensor of a display device according to an embodiment of the disclosure.

Referring to FIG. 11, in an embodiment, the display panel 10 includes a display driver circuit DC_PX that controls the amount of light emitted by the plurality of pixels PX. The panel driver 20 transmits a driving signal or a driving voltage to one or more transistors and various signal lines in the display driver circuit DC_PX associated with each of the plurality of pixels PX.

The display panel 10 also includes a sensing driver circuit DC_PS that controls the amount of light received by the photo sensors PS. The panel driver 20 transmits a driving signal or a driving voltage to one or more transistors and various signal lines in the sensing driver circuit DC_PS associated with each of the plurality of photo sensors PS, and receives an electrical sensing signal based on the light incident to the photo sensor PS.

The display driver circuit DC_PX and the sensing driver circuit DC_PS may be separately formed as integrated circuits, or may be formed as a single integrated circuit as shown in FIG. 11.

The display driver circuit DC_PX includes a light-emitting element EL, a capacitor Cst, a first transistor T1 and a second transistor T2. The display driver circuit DC_PX receives a data signal DATA, a first scan signal GW, the first supply voltage ELVDD and the second supply voltage ELVSS. The data signal DATA is received from the data driver 23 through the data lines DL, and the first scan signal GW is received from the scan driver 22 through the scan lines SL.

The light-emitting element EL is an organic light-emitting diode that includes an anode electrode, a cathode electrode, and an emissive layer EML disposed between the anode electrode and the cathode electrode. The anode electrode of the light-emitting element EL is connected to the first transistor T1. The cathode electrode of the light-emitting element EL is connected to a second supply voltage ELVSS terminal to receive the second supply voltage ELVSS. The anode electrode of the light-emitting element EL corresponds to the pixel electrode AE of FIG. 6, and the cathode electrode thereof corresponds to the common electrode CE of FIG. 6.

The capacitor Cst is connected between the gate electrode of the first transistor T1 and a first supply voltage ELVDD terminal. The capacitor Cst includes a capacitor first electrode connected to the gate electrode of the first transistor T1 and a capacitor second electrode connected to the first supply voltage ELVDD terminal.

The first transistor T1 is a driving transistor, and the second transistor T2 is a switching transistor. Each of the transistors includes a gate electrode, a source electrode and a drain electrode. One of the source electrode and the drain electrode is a first electrode and the other is a second electrode. In the following description, for convenience of illustration, an example is described where the drain electrode is the first electrode and the source electrode is the second electrode.

The first transistor T1 is a driving transistor and generates a driving current. The gate electrode is connected to the capacitor first electrode, the second electrode is connected to the first supply voltage ELVDD terminal, and the first electrode is connected to the anode electrode of the light-emitting element EL. The capacitor second electrode is connected to the first electrode of the first transistor T1. In the cross-sectional view of FIG. 6, the first transistor T1 is disposed on the thin-film transistor layer 100 and may correspond to the first thin-film transistor TFT1 or the second thin-film transistor TFT2.

The second transistor T2 is a switching transistor, and includes a gate electrode connected to the first scan signal GW terminal, a second electrode connected to a data signal DATA terminal, and a first electrode connected to the gate electrode and, through the capacitor Cst, to the first electrode of the first transistor T1. The second transistor T2 is turned on in response to the first scan signal GW and performs a switching operation that transmits the data signal DATA to the first electrode and the gate electrode of the first transistor T1. The second transistor T2 may be disposed on the transistor layer 100 such as the first film transistor TFT1.

The capacitor Cst is charged with a voltage that corresponds to the data signal DATA received from the second transistor T2. The first transistor T1 controls the driving current that flows into the light-emitting element EL in proportion to the amount of charge stored in the capacitor Cst.

However, the above-described configuration merely illustrative, and embodiments are not limited thereto. In an embodiment, the display driver circuit DC_PX further includes a compensation circuit that compensates threshold voltage deviations ΔVth of the first transistor T1.

The sensing driver circuit DC_PS includes a sensing transistor LT1, a reset transistor LT2 and a photoelectric conversion element PD. In addition, the sensing driver circuit DC_PS further includes a sensing node LN between the sensing transistor LT1, the reset transistor LT2 and the photoelectric conversion element PD. The sensing driver circuit DC_PS receives a fingerprint scan signal LD, a fingerprint sensing signal RX, and a reset signal RST. The fingerprint scan signal LD is received, but is not limited to, from the scan driver 22 through the scan lines SL. The fingerprint sensing signal RX is received from the fingerprint sensing unit 25 through the sensing lines RL. The reset signal RST is received from the reset signal generating unit 26 through the reset signal line RSTL.

The photoelectric conversion element PD may be an organic light-emitting diode or a phototransistor that includes an anode electrode, a cathode electrode, and a photoelectric conversion layer PEL disposed between the anode electrode and the cathode electrode. The anode electrode of the photoelectric conversion element PD is connected to the sensing node LN. The cathode electrode of the photoelectric conversion element PD is connected to a second supply voltage ELVSS terminal to receive the second supply voltage ELVSS. The anode electrode of the photoelectric conversion element PD corresponds to the first electrode E1 of FIG. 6, and the cathode electrode thereof corresponds to the common electrode CE of FIG. 6.

The photoelectric conversion element PD generates photocharges when it is exposed to external light. The generated photocharges accumulate in the anode electrode of the photoelectric conversion element PD. The voltage at the sensing node LN electrically connected to the anode electrode steps up. When a fingerprint sensing signal RX terminal is connected to the photoelectric conversion element PD, an electric current flows due to a voltage difference between the voltage at the sensing node LN where charges are accumulated and the voltage of the sensing line RL.

The sensing transistor LT1 has a gate electrode connected to the fingerprint scan signal LD terminal, a second electrode connected to the sensing node LN, and a first electrode connected to the fingerprint sensing signal RX terminal. The sensing transistor LT1 is turned on in response to the fingerprint scan signal LD and transmits a current received from the photoelectric conversion element PD to the fingerprint sensing signal RX terminal. As shown in FIG. 6, the sensing transistor LT1 corresponds to the first sensing transistor LT1 of the thin-film transistor layer 100.

The reset transistor LT2 has a gate electrode connected to the reset signal RST terminal, a second electrode connected to the first supply voltage ELVDD terminal, and a first electrode connected to the sensing node LN. The sensing node LN and the anode electrode of the photoelectric conversion element PD are reset to the first supply voltage ELVDD.

Although the transistors in the drawings are NMOS transistors, embodiments are not limited thereto, and in some embodiments, some or all of the transistors are implemented as PMOS transistors.

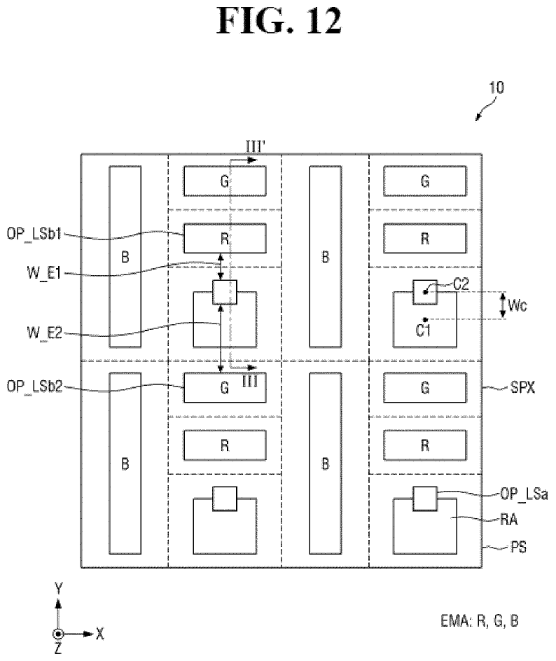

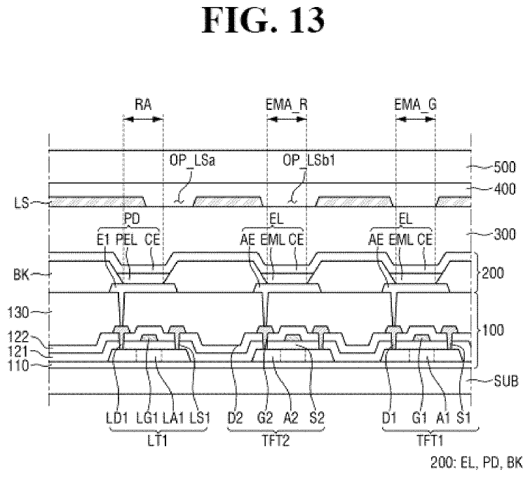

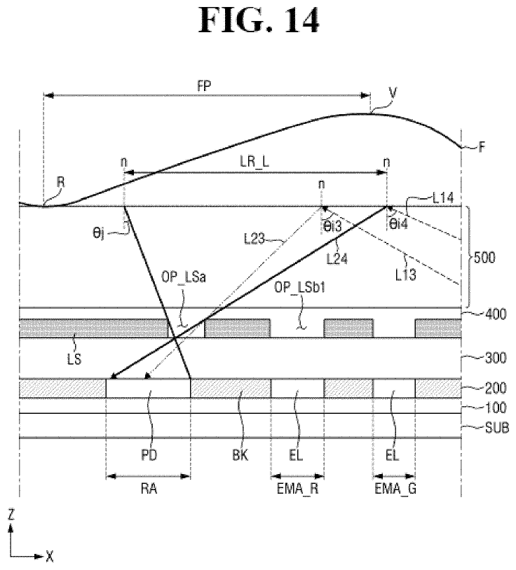

Hereinafter, a display device according to an embodiment will be described with reference to FIGS. 12 to 14. FIG. 12 is a plan view of a layout of pixels and photo sensors of a display panel according to an embodiment. FIG. 13 is a cross-sectional view taken along line III-III′ of FIG. 12. FIG. 14 is a schematic cross-sectional view of the display panel of FIG. 13.

An embodiment of FIGS. 12 to 14 differs from an above-described embodiment in that a green light-emitting unit G, a red light-emitting unit R, a blue light-emitting unit B and a light-sensing unit RA disposed on a display panel 10 of a display device 1 have a different layout.

According to an embodiment of the disclosure, the green light-emitting unit G, the red light-emitting unit R, the blue light-emitting unit B and the light-sensing unit RA are repeatedly arranged in a matrix. The blue light-emitting units B are arranged and spaced apart in the second direction Y and form a first column while the green light-emitting units G and the red light-emitting units G are alternately arranged in the second direction Y and form a second column adjacent to the first column. The light-emitting units EMA are repeatedly arranged in this manner up to the n^{th} column.

The combination of a green light-emitting unit G, a red light-emitting unit R and a blue light-emitting unit B arranged on the display panel 10 forms a single unit pixel.

Different light-emitting units EMA have different areas. For example, the blue light-emitting units B are larger than the green light-emitting units G and the red light-emitting units R. Although the light-emitting units EMA have a rectangular or square shape when viewed from the top, embodiments of the disclosure are not limited thereto. They may have other shapes, such as an octagon, a circle or a diamond.

When the photo sensors PS are disposed in the photo sensing area PSA that overlap the display area DA, the blue light-emitting units B are arranged in columns in the second direction Y that are spaced apart from one another by a predetermined distance, and the green light-emitting units G, the red light-emitting units R and the light-sensing units RA are repeatedly arranged in this order in the second direction Y in the other columns. For example, in one second column, the green light-emitting units G, the red light-emitting units R and the light-sensing units RA are repeatedly arranged in this order in the second direction Y.

The light-shielding layer LS, which have light-emitting openings OP_LSb1 and OP_LSb2 and light-shielding openings OP_LSa, are disposed on the light-emitting units EMA and the light-sensing units RA.

The light-emitting openings OP_LSb1 and OP_LSb2 pass lights L13 and L14 emitted from the light-emitting element EL in the third direction Z where the light-emitting openings OP_LSb1 and OP_LSb2 overlap the light-emitting units EMA. The light-shielding opening OP_LSa passes lights L23 and L24 emitted from the photoelectric conversion element PD in the third direction Z where the light-shielding opening OP_LSa overlaps the light-sensing unit RA.

The light-shielding opening OP_LSa is located adjacent to one side of each light-sensing unit RA. The center C1 of the light-sensing unit RA is spaced apart from the center C2 of the light-shielding opening OP_LSa by a distance Wc. Accordingly, the light-shielding opening OP_LSa is disposed closer to the red light-emitting unit R than to the green light-emitting unit G. The red light-emitting unit R forms the same unit pixel as the light-sensing unit RA, whereas the green light-emitting unit G forms a different unit pixel from the light-sensing unit RA. However, embodiments of the disclosure are not limited thereto.

The first light-emitting opening OP_LSb1 of the light-shielding layer LS overlaps the green light-emitting unit G, and the second light-emitting opening OP_LSb2 overlaps the red light-emitting unit R.

The minimum distance between the first light-emitting opening OP_LSb1 and the light-shielding opening OP_LSa is defined as a first distance W_E1, and the minimum distance between the second light-emitting opening OP_LSb2 and the light-shielding opening OP_LSa is defined as a second distance W_E2. The first distance W_E1 differs from the second distance W_E2. More specifically, the first distance W_E1 is shorter than the second distance W_E2.

In addition, due to the distance Wc, at least a part of the light-shielding opening OP_LSa overlaps the bank layer BK in the third direction Z. For example, at least a part of the light-shielding opening OP_LSa does not overlap the light-sensing unit RA.

Referring to FIG. 13, in an embodiment, an emissive layer EML is disposed on the pixel electrode AE of the light-emitting element EL exposed by the opening of the bank layer BK. The emissive layer EML includes a high-molecular weight material or a low-molecular weight material, and emits one of red, green or blue light from the sub-pixels SPX, respectively, in each pixel PX. The light emitted from the emissive layer EML contributes to the image display or functions as a light source for the photo sensor PS.

For example, when the emission layer EML emits red light, the area where the exposed pixel electrode AE and the emissive layer EML overlap each other is referred to as the red emission R. For example, when the emissive layer EML emits green light, the area where the exposed pixel electrode AE and the emissive layer EML overlap each other is referred to as the green emission G.

Referring to FIG. 14, in an embodiment, the amount of light that has an angle formed by the light emitted from the light-emitting element EL and the normal line n orthogonal to the interface of the cover window 500 exceeds the critical angle of total reflection is increased.

For example, a third total reflection angle θi3 is a critical angle, and a fourth total reflection angle θi4 is the maximum total reflection angle within the light incident the region or area LR on the light-sensing unit RA. The third total reflection angle θi3 is smaller than the fourth total reflection angle θi4. In addition, a first incident angle θj refers to the incident angle that has the largest absolute value in the negative (−) direction of the light incident on the light-sensing unit RA from the light-shielding opening OP_LS.

The light L13 emitted from the light-emitting element EL and that has the third total reflection angle θi3 is totally reflected at the interface of the cover window 500. The reflected light L23 is incident on the light-sensing unit RA. In addition, the light L14 emitted from the light-emitting element EL and that has the fourth total reflection angle θi4 is totally reflected at the interface of the cover window 500. The reflected light L24 is incident on the light-sensing unit RA.

In this instance, the length LR_L of the light incident region or area LR on the light-sensing unit RA is determined by the light incident at the first incident angle θj and the light L24 reflected at the fourth total reflection angle θi4.

In particular, the light incident region or area LR on the light-sensing unit RA can achieve a high amount of received light where the totally reflected light at the third total reflection angle θi3 and the fourth total reflection angle θi4 are collected.

As described above, in the display device 1 according to an embodiment where the light-shielding opening OP_LSa is located on one side of the light-sensing unit RA, the amount of light incident on the photoelectric conversion element PD with the total reflection angle increases while the light incident region LR on the light-sensing unit RA is maintained.

In addition, even without decreasing the width W_RA of the light-sensing unit RA and the width W_OP of the light-shielding opening OP_LSa, the region of the light LR incident on the light-sensing unit RA that can distinguish between the ridges R and the valleys V of the fingerprint F is maintained, so that the accuracy of fingerprint sensing is increased.

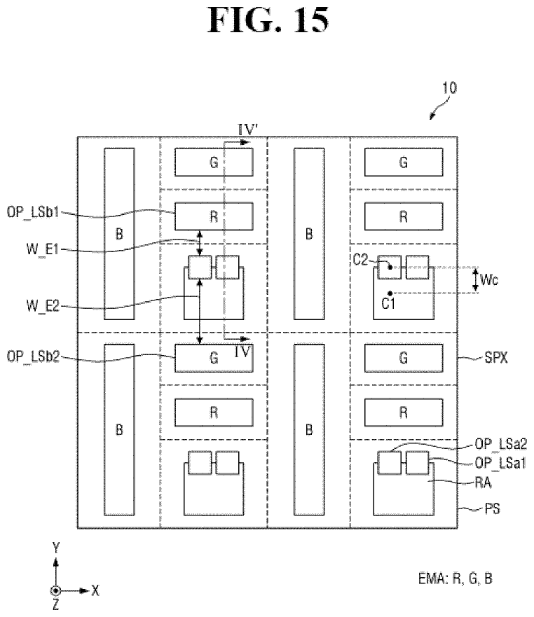

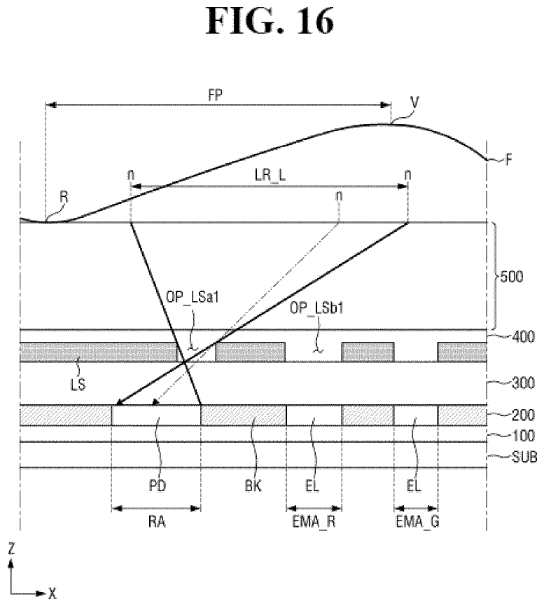

Hereinafter, a display device according to an embodiment will be described with reference to FIGS. 15 to 16. FIG. 15 is a plan view of a layout of pixels and photo sensors of a display panel according to an embodiment. FIG. 16 is a schematic cross-sectional view of a display panel of FIG. 15, taken along line IV-IV′ of FIG. 15.

A display device 1 according to an embodiment differs from that of FIGS. 12 to 14 in that a light-shielding layer LS adjacent to a light-sensing unit RA includes a plurality of light-shielding openings OP_LSa1 and OP_LSa2.

The plurality of light-shielding openings OP_LSa1 and OP_LSa2 overlap a single light-sensing unit RA. The plurality of light-shielding openings OP_LSa1 and OP_LSa2 are located along the first direction X.

When the light-shielding openings OP_LSa1 and OP_LSa2 are located along the first direction X, the distance between the first light-shielding opening OP_LSa1 and the first light-emitting opening OP_LSb1 is equal to the distance between the second light-shielding opening OP_LSa2 and the first light-emitting opening OP_LSb1. In addition, the distance between the first light-shielding opening OP_LSa1 and the second light-emitting opening OP_LSb2 is equal to the distance between the second light-shielding opening OP_LSa2 and the second light-emitting opening OP_LSb2.

The display device 1 according to an embodiment includes the plurality of light-shielding openings OP_LSa1 and OP_LSa2 that overlap the single light-sensing unit RA, and thus the width of each of the plurality of light-shielding openings OP_LSa1 and OP_LSa2 is smaller than that of one light-shielding opening. As the width of each of the openings is small, the influence of noise light that is emitted from the light-emitting unit EMA and is incident on the photoelectric conversion element PD can be suppressed.

In the display device 1 according to an embodiment, the amount of light that is totally reflected from and incident on the photoelectric conversion element PD can increase, and the length LR_L of the light incident region or area LR on the light-sensing unit RA is constant, which increases the accuracy of the fingerprint sensing. In addition, since the influence of noise light is suppressed, more accurate sensing sensitivity can be achieved.

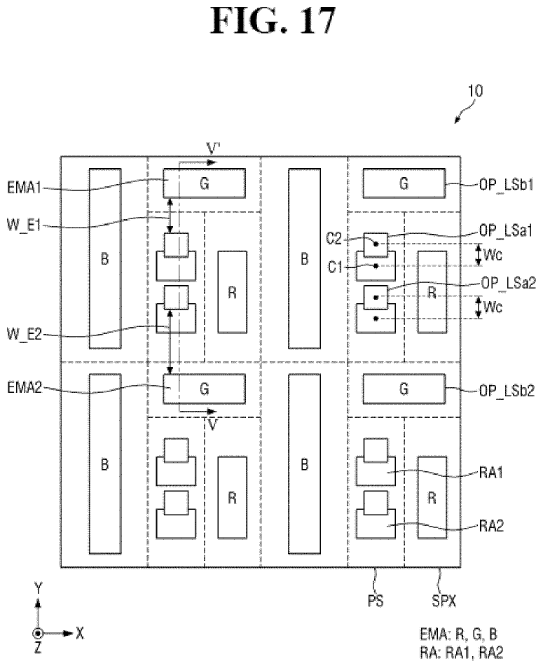

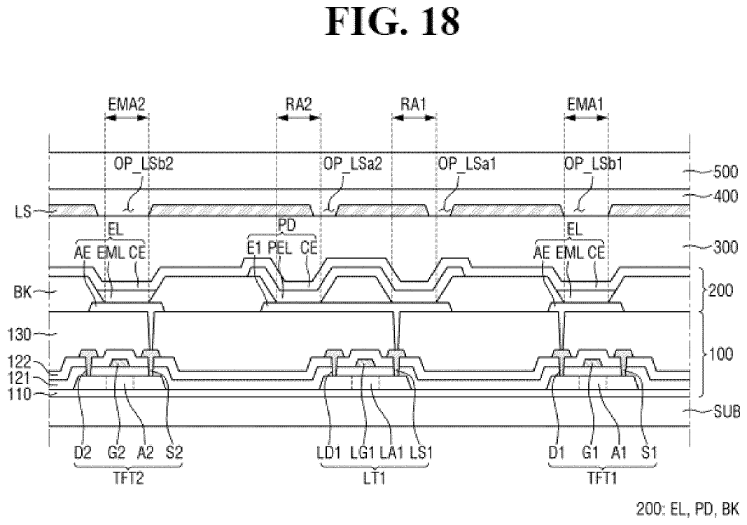

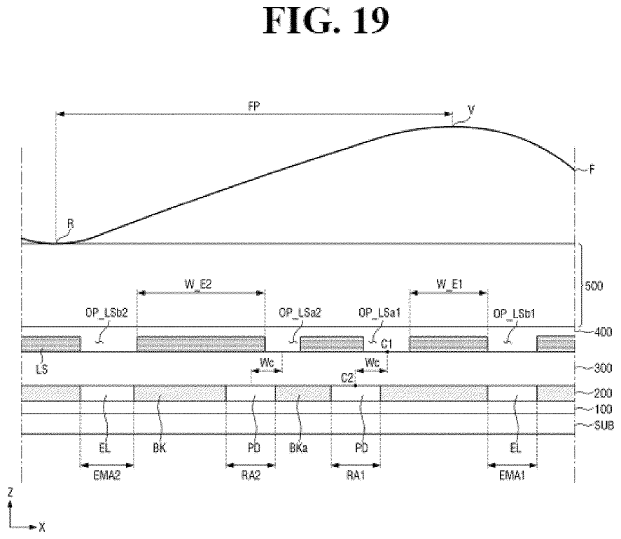

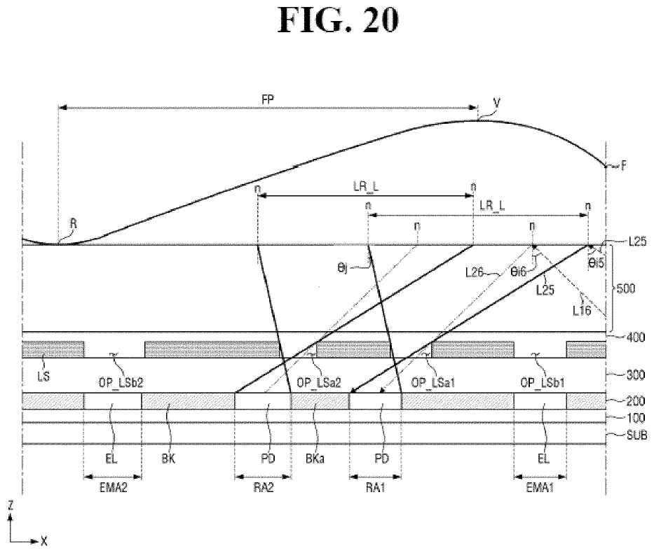

Hereinafter, a display device according to an embodiment will be described with reference to FIGS. 17 to 20. FIG. 17 is a plan view of a layout of pixels and photo sensors of a display panel according to an embodiment. FIG. 18 is a cross-sectional view taken along line V-V′ of FIG. 17. FIG. 19 is a schematic cross-sectional view of a display panel of FIG. 18. FIG. 20 is a cross-sectional view of incident light in an example shown in FIG. 19.

A display device 1 according to an embodiment differs from that of FIGS. 5 to 8 in that the layout of light-emitting units EMA is different, and that a light-shielding layer LS that overlaps a light-sensing unit RA includes a plurality of light-shielding openings OP_LSa1 and OP_LSa2.

Referring to FIG. 17, in an embodiment, the green light-emitting unit G, the red light-emitting unit R, the blue light-emitting unit B and the light sensing area RA are repeatedly arranged in a matrix. The blue light-emitting units B are arranged and spaced apart in the second direction Y and form a first column while the green light-emitting units G and the red light-emitting units G are alternately arranged in the second direction Y and form a second column adjacent to the first column.

In the drawings, the longer sides of a rectangular shaped blue light-emitting unit B are parallel to the second direction Y. The longer sides of a rectangular shaped green light-emitting unit G are parallel to the first direction X, and the longer sides of a rectangular shaped red light-emitting unit R are parallel to the second direction Y. For example, the longer sides of the green light-emitting unit G and the shorter sides of the red light-emitting unit R face each other. However, embodiments of the layout of the light-emitting units EMA are not limited thereto.

Different light-emitting units EMA have different areas. For example, the blue light-emitting units B are larger than the green light-emitting units G and the red light-emitting units R. However, embodiments of the disclosure are not limited thereto.

When the photo sensors PS are disposed in the light sensing area PSA that overlaps the display area DA, the blue light-emitting units B are arranged in first columns in the second direction Y and are spaced apart from one another by a predetermined distance, and the green light-emitting units G, the red light-emitting units R and the light sensing areas RA are repeatedly arranged in this order in the second direction Y in second columns. For example, the green light-emitting unit G is disposed in the second column, and the light-sensing unit RA and the red light-emitting unit EMA_R are disposed side by side on a lower side of the green light-emitting unit G, with their longer sides facing each other.

The light-shielding layer LS disposed on the light-sensing unit RA. The light-sensing unit RA includes a first light-sensing unit RA1 and a second light-sensing unit RA2 adjacent to each other in the second direction Y. The light-shielding layer LS includes a plurality of light-shielding openings OP_LSa1 and OP_LSa2 that overlap the first light-sensing unit RA1 and the second light-sensing unit RA2. For example, the plurality of light-shielding openings OP_LSa1 and OP_LSa2 include a first light-shielding opening OP_LSa1 and a second light-shielding opening OP_LSa2. The first light-shielding opening OP_LSa1 may overlap the first light-sensing unit RA1 and the second light-shielding opening OP_LSa2 may overlap the second light-sensing unit RA2. The plurality of light-shielding openings OP_LSa1 and OP_LSa2 are adjacent to each other in the second direction Y on the light-sensing unit RA, but embodiments of the disclosure are not limited thereto.

The light-shielding openings OP_LSa1 and OP_LSa2 are adjacent to one side of each light-sensing unit RA. For example, the first light-shielding opening OP_LSa1 is adjacent to one side of the first light-sensing unit RA1 in the second direction Y and the second light-shielding opening OP_LSa2 is adjacent to one side of the second light-sensing unit RA2 in the second direction Y.

The center C1 of the first light-sensing unit RA1 is spaced apart from the center C2 of the first light-shielding opening OP_LSa1 by a distance Wc. In addition, the second light-shielding opening OP_LSa2 and the second light-sensing unit RA2 are spaced apart from each other by a distance Wc to the center thereof.

the center C1 of the light-sensing unit RA is equally spaced apart from the center of the second light-shielding opening OP_LSa2.

Accordingly, at least a part of the first light-shielding opening OP_LSa1 overlaps each first light-sensing unit RA1, and at least another part of the first light-shielding opening OP_LSa1 overlaps a division bank layer BKa, shown in FIG. 19. In addition, at least a part of the second light-shielding opening OP_LSa2 overlaps each second light-sensing unit RA2, and at least another part of the second light-shielding opening OP_LSa2 overlaps the bank layer BK, shown in FIG. 18.

According to an embodiment, of the green light-emitting units G, the red light-emitting units R and the blue light-emitting units B in each sub-pixel SPX, the light-emitting unit disposed on one side of the light-sensing unit RA in the second direction Y is referred to as a first light-emitting unit EMA1, while the light-emitting unit disposed on the opposite side of the light-sensing unit RA in the second direction Y is referred to as a second light-emitting unit EMA2.

The first light-emitting opening OP_LSb1 of the light-shielding layer LS overlaps the first light-emitting unit EMA1, and the second light-emitting opening OP_LSb2 overlaps the second light-emitting unit EMA2.

Due to the distance Wc, the first light-shielding opening OP_LSa1 is located adjacent to the first light-emitting unit EMA1, and the second light-shielding opening OP_LSa2 is located adjacent to the second light-emitting unit EMA2. In addition, the minimum distance between the first light-emitting opening OP_LSb1 and the first light-shielding opening OP_LSa1 is defined as a first distance W_E1, and the minimum distance between the second light-emitting opening OP_LSb2 and the second light-shielding opening OP_LSa2 is defined as a second distance W_E2. The first distance W_E1 differs from the second distance W_E2. More specifically, the first distance W_E1 is shorter than the second distance W_E2.

Referring to FIGS. 18 to 20, in an embodiment, the light-emitting element layer 200 includes a photoelectric conversion element PD, a light-emitting element EL, and a bank layer BK. The photoelectric conversion element PD includes a first electrode E1 electrically connected to the thin-film transistor layer 100, a photoelectric conversion layer PEL disposed on the first electrode E1, and a common electrode disposed on the photoelectric conversion layer PEL.

In the display device 1 according to an embodiment, a division bank layer BKa further covers a part of the upper surface of the first electrode E1 of the photoelectric conversion element PD.

The division bank layer BKa overlaps a part of the upper surface of the first electrode E1, and the bank layer BK overlaps both side surfaces of the first electrode E1. The bank layer BK and the division bank layer BKa form a plurality of openings that expose the first electrode E1. The opening provides a space in which the photoelectric conversion layer PEL is formed, and the areas where the exposed first electrode E1 and the photoelectric conversion layer PEL overlap each other are defined as the first light-sensing unit RA1 and the second light-sensing unit RA2. For example, the division bank layer BKa covers a part of the upper surface of the first electrode E1 and partitions the first light-sensing unit RA1 and the second light-sensing unit RA2.

The first light-sensing unit RA1 partially overlaps the first light-shielding opening OP_LSa1, and the second light-sensing unit RA2 partially overlaps the second light-shielding opening OP_LSa2.

The division bank layer BKa is formed by the same process as the bank layer BK. The bank layer BK and the division bank layer BKa are simultaneously patterned above the first electrode E1. Accordingly, the division bank layer BKa and the bank layer BK include the same material.

The division bank layer BKa is disposed on the upper surface of the first electrode and partitions the same number of light-sensing units as the number of the plurality of light-shielding openings OP_LSa1 and OP_LSa2. For example, since the division bank layer BKa partitions the light-sensing units RA of the photoelectric conversion element PD, incident light that passes through the first light-shielding opening OP_LSa1 and incident on the photoelectric conversion element PD can be adjusted so that it is incident only on the first light-sensing unit RA1. In addition, incident light that passes through the second light-shielding opening OP_LSa2 and incident on the photoelectric conversion element PD can be adjusted so that it is incident only on the second light-sensing unit RA2.

The photoelectric conversion layer PEL is disposed on the first electrode E1 of the photoelectric conversion element PD exposed by the division bank layer BKa and the bank layer BK. Light is incident on the first light-sensing unit RA1 and the second light-sensing unit RA2, while no light is incident on the part of the first electrode E1 that is not exposed by the division bank layer BKa.

The common electrode CE is disposed on the photoelectric conversion layer PEL. The common electrode CE is disposed across a plurality of sub-pixels SPX and the photo sensors PS and covers the emissive layer EML and the bank layer BK in addition to the photoelectric conversion layer PEL.

The photoelectric conversion element PD and the light-emitting element EL share the common electrode CE disposed on the photoelectric conversion layer PEL and the emissive layer EML, however, embodiments of the disclosure are not limited thereto.

FIG. 20 shows that the first light-shielding opening OP_LSa1 transmits the reflected light L25 when the light L15 emitted from one of the plurality of light-emitting units EMA is reflected from the interface of the cover window 500. The reflected light L25 transmitted the first light-shielding opening OP_LSa1 is incident on the photoelectric conversion layer PEL disposed in the first light-sensing unit RA1. In addition, the second light-shielding opening OP_LSa2 transmits light output from one of the plurality of light-emitting units EMA and reflected from the interface of the cover window 500 toward the photoelectric conversion layer PEL disposed in the second light-sensing unit RA2.

A distance LR_L of the light incident region or area LR on the light-sensing unit RA is determined by the reflected light incident through the first light-shielding opening OP_LSa1. For example, the distance LR_L of the light incident region LR on the first light-sensing unit RA1 is determined by the light that has the first incident angle θj and the light L26 that has the sixth total reflection angle θi6.

Herein, the first incident angle θj refers to the incident angle of the light incident on the light-sensing unit RA from the light-shielding opening OP_LS that has the largest absolute value in the negative (−) direction. For example, a fifth total reflection angle θi5 is a critical angle, and a sixth total reflection angle θi6 is the maximum total reflection angle within the light incident region LR on the light-sensing unit RA. The fifth total reflection angle θi5 is smaller than the sixth total reflection angle θi6.

In addition, the distance LR_L of the light incident region LR on the second light sensing area RA2 is determined by the reflected light incident through the second light-shielding opening OP_LSa2. Accordingly, the distance LR_L of the light incident region LR on one photoelectric conversion element PD that includes the first light-sensing unit RA1 and the second light-sensing unit RA2 is determined by the reflected light incident through the first light-shielding opening OP_LSa1 and the reflected light incident through the second light-shielding opening OP_LSa2.

In particular, the light incident region or area LR on the light-sensing unit RA can achieve a high amount of the received light where the totally reflected lights at the total reflection angle are collected.

When the light-shielding openings OP_LSa1 and OP_LSa2 are located adjacent to one side of each light-sensing unit RA, the amount of light incident on the photoelectric conversion element PD with the total reflection angle is increased while the distance LR_L of the light incident region LR on the light-sensing unit RA in the direction is maintained.

Accordingly, it is possible to maintain the width W_RA of the light-sensing unit RA and the width W_OP of the light-shielding opening OP_LSa and to distinguish between the ridges R and the valleys V of the fingerprint F, so that the accuracy of fingerprint sensing can be increased.

Features of various embodiments of the disclosure can be combined partially or totally. As will be clearly appreciated by those skilled in the art, technically various interactions and operations are possible. Various embodiments can be practiced individually or in combination.

In concluding the detailed description, those skilled in the art will appreciate that many variations and modifications can be made to embodiments without substantially departing from the principles of the disclosure. Therefore, embodiments of the disclosure are used in a generic and descriptive sense only and not for purposes of limitation.

What is claimed is:

1. A display device, comprising:
a substrate;
a plurality of light-emitting units disposed on the substrate and that emit light;
a bank layer disposed on the substrate and that partitions the plurality of light-emitting units;
a plurality of light-sensing units disposed on the substrate and that sense incident light; and
a light-shielding layer disposed on the bank layer and that includes a light-shielding opening that overlaps each of the light-sensing units,
wherein at least a part of the light-shielding opening overlaps the bank layer.

2. The display device of claim 1,
wherein the plurality of light-emitting units includes a first light-emitting unit disposed on one side of one of the plurality of light-sensing units; and a second light-emitting unit disposed on an opposite side of the one of the plurality of light-sensing units, and
the light-shielding opening is located adjacent to the first light-emitting unit.

3. The display device of claim 2,
wherein the light-shielding layer further includes a first light-emitting opening that overlaps the first light-emitting unit; and a second light-emitting opening that overlaps the second light-emitting unit.

4. The display device of claim 3,
wherein, letting a minimum distance between the first light-emitting opening and the light-shielding opening is defined as a first distance, and a minimum distance between the second light-emitting opening and the light-shielding opening is defined as a second distance, and
the first distance differs from the second distance.

5. The display device of claim 4,
wherein a difference between the first distance and the second distance is greater than a distance between a center of one of the light-sensing units and a center of a light-shielding opening that overlaps the one of the light-sensing units.

6. The display device of claim 2,
wherein a distance between a center of one of the light-sensing units and a center of a light-shielding opening that overlaps the one of the light-sensing units is at least half a length of the one of the light-sensing units.

7. The display device of claim 1, further comprising:
an emissive layer disposed in each of the light-emitting units;
a photoelectric conversion layer disposed in each of the light-sensing units; and
a common electrode disposed on the emissive layer and the photoelectric conversion layer.

8. A display device, comprising:
a substrate;
a plurality of light-emitting units disposed on the substrate and that emit light;
a bank layer disposed on the substrate and that partitions the plurality of light-emitting units;
a plurality of light-sensing units disposed on the substrate and that sense incident light; and
a light-shielding layer disposed on the bank layer and that includes a light-shielding opening that overlaps each of the light-sensing units,
wherein the plurality of light-emitting units include a first light-emitting unit disposed on one side of a light-sensing unit of the plurality of light-sensing units and a second light-emitting unit disposed on an opposite side of the light-sensing unit of the plurality of light-sensing units, and
the light-shielding opening is located adjacent to the first light-emitting unit.

9. The display device of claim 8,
wherein the light-shielding layer includes a first light-emitting opening that overlaps the first light-emitting unit; and a second light-emitting opening that overlaps the second light-emitting unit, and
a minimum distance between the first light-emitting opening and the light-shielding opening differs from a minimum distance between the second light-emitting opening and the light-shielding opening.

10. The display device of claim 8,
wherein the first light-emitting unit and the second light-emitting unit are alternately arranged, and each of the light-sensing units is disposed between the first light-emitting unit and the second light-emitting unit.

11. The display device of claim 8,
wherein the first light-emitting unit and the second light-emitting unit emit a same color light.

12. The display device of claim 8,
Wherein the light-shielding opening includes a first light-shielding opening and a second light-shielding opening that overlaps one of the light-sensing units.

13. A display device, comprising:
a substrate;
a light-emitting element disposed on the substrate and that includes a plurality of light-emitting units that emit light;
a first electrode disposed on the substrate;
a bank layer disposed on the substrate and that includes an opening that exposes at least a part of the first electrode;
a photoelectric conversion layer disposed on the first electrode exposed by the opening; and
a light-shielding layer disposed on the photoelectric conversion layer and that includes a first light-shielding opening,
wherein the first light-shielding opening overlaps the bank layer.

14. The display device of claim 13,
wherein the light-shielding layer further includes a second light-shielding opening adjacent to the first light-shielding opening.

15. The display device of claim 14,
wherein the photoelectric conversion layer includes a first light-sensing unit and a second light-sensing unit that overlap the first electrode,
the first light-sensing unit overlaps the first light-shielding opening, and
the second light-sensing unit overlaps the second light-shielding opening.

16. The display device of claim 15, further comprising:
a division bank layer that covers a part of an upper surface of the first electrode and partitions the first light-sensing unit and the second light-sensing unit,
wherein the photoelectric conversion layer is disposed on the upper surface of the first electrode in the first light-sensing unit and the second light-sensing unit.

17. The display device of claim 15, wherein the plurality of light-emitting units comprises:
a first light-emitting unit adjacent to the first light-sensing unit; and
a second light-emitting unit adjacent to the second light-sensing unit,
wherein the first light-shielding opening and the second light-shielding opening are located closer to the first light-emitting unit than to the second light-emitting unit.

18. The display device of claim 17, wherein the light-shielding layer comprises:
a first light-emitting opening that overlaps the first light-emitting unit; and
a second light-emitting opening that overlaps the second light-emitting unit, and
wherein a minimum distance between the first light-emitting opening and the first light-shielding opening differs from a minimum distance between the second light-emitting opening and the second light-shielding opening.

19. The display device of claim 17,
wherein the first light-emitting unit and the second light-emitting unit are alternately arranged, and
the first light-sensing unit and the second light-sensing unit are disposed between the first light-emitting unit and the second light-emitting unit.

20. The display device of claim 16,
wherein the first light-shielding opening overlaps the bank layer, and
the second light-shielding opening overlaps the division bank layer.
